(19) United States
(12) Patent Application Publication
(10) Pub. No.: US 2023/0253484 A1
(43) Pub. Date: Aug. 10, 2023

(54) ADVANCED 3D DEVICE ARCHITECTURE USING NANOSHEETS WITH 2D MATERIALS FOR SPEED ENHANCEMENT

(71) Applicant: Tokyo Electron Limited, Tokyo (JP)

(72) Inventors: H. Jim Fulford, Albany, NY (US); Mark I. Gardner, Albany, NY (US); Partha Mukhopadhyay, Albany, NY (US)

(73) Assignee: Tokyo Electron Limited, Tokyo (JP)

(21) Appl. No.: 17/667,378

(22) Filed: Feb. 8, 2022

(51) Int. Cl. H01L 29/66; H01L 29/40; H01L 29/786; H01L 27/12; H01L 21/84; H01L 29/423; H01L 29/06

(52) U.S. Cl. CPC H01L 29/66969; H01L 29/66045; H01L 29/401; H01L 29/78696; H01L 27/1203; H01L 21/84; H01L 29/42392; H01L 29/0673

(57) ABSTRACT

Methods for the manufacture of semiconductor devices constructed advanced three-dimensional (3D) device architectures using nanosheets with two-dimensional (2D) materials are disclosed. Aspects can include forming a dielectric layer; forming a conductive oxide layer on the dielectric layer; selectively forming a two-dimensional (2D) material around the conductive oxide layer; forming an active gate around the 2D material; and forming a first metal structure and a second metal structure, wherein the dielectric layer and conductive oxide layer extend between the first metal structure and the second metal structure.

### TECHNICAL FIELD

The present invention relates generally to the field of manufacturing semiconductor devices.

### BACKGROUND

In the manufacture of semiconductor devices (especially on the microscopic scale), various fabrication processes are executed, such as film-forming depositions, etch mask creation, patterning, material etching and removal, and doping treatments. These processes are performed repeatedly to form desired semiconductor device elements on a substrate. Conventional microfabrication techniques only manufacture transistors in one active device plane, while wiring or metallization is formed above the active device plane. Such devices are accordingly characterized as two-dimensional (2D) circuits, manufactured using 2D fabrication techniques. Although scaling efforts have greatly increased the number of transistors per unit area in 2D circuits, these 2D fabrication techniques are approaching physical atomic limitations with single digit nanometer semiconductor device fabrication nodes. Semiconductor device fabricators have expressed a desire for semiconductor circuits in which transistors have increased complexity and dimensionality.

### SUMMARY

A variety of semiconductor devices that integrate conductive oxide and 2D materials are proposed, which aim to overcome scaling limitations experienced in planar devices by increasing transistor density in volume rather than area. The devices and methods may utilize nanosheet masks to form openings in stacks of layers, allowing for precise deposition or formation of 2D materials and other semiconductor materials. Such 2D materials have the potential for very high mobility, and therefore enable sub-nanometer channel thickness regions. Such techniques can enable future nanoscale transistors which may be implemented in a variety of logical circuits, including central processing units (CPUs), graphics processing units (GPUs), and field-programmable gate arrays (FPGAs).

In an embodiment, a method may comprise forming a dielectric layer; forming a conductive oxide layer on the dielectric layer; selectively forming a two-dimensional (2D) material around the conductive oxide layer; forming an active gate around the 2D material; and forming a first metal structure and a second metal structure, wherein the dielectric layer and conductive oxide layer extend between the first metal structure and the second metal structure.

The conductive oxide layer, first metal structure, and second metal structure may be formed on a dielectric. Forming the conductive oxide layer of the structure may comprise removing the conductive oxide layer via gate openings; and forming the conductive oxide layer on the dielectric layer via the gate openings. Selectively forming the 2D material may comprise depositing the 2D material on the conductive oxide layer via the gate openings. Forming the active gate may comprise forming a high-k dielectric material on the 2D material; and forming a gate metal on the high-k dielectric material. The first metal structure and the second metal structure may be selectively deposited in contact with the conductive oxide layer.

The method may further comprise forming the first metal structure and the second metal structure in contact with the dielectric layer, the conductive oxide layer, and the 2D material. The method may further comprise forming a dielectric material that isolates the first metal structure and the second metal structure from the active gate. The method may further comprise forming a second dielectric layer; forming a second conductive oxide layer on the second dielectric layer; selectively forming a second 2D material around the second conductive oxide layer; forming a second active gate around the second 2D material; and forming a third metal structure and a third metal structure, wherein the second dielectric layer and second conductive oxide layer extend between the third metal structure and the fourth metal structure.

In another embodiment, a device may comprise a dielectric extending from a first source/drain contact to a second source drain contact; a conductive oxide material on a portion of the dielectric; a 2D material around the dielectric and extending from the first source/drain contact to the second source drain contact; and an active gate around the 2D material.

The active gate may be isolated from the first source/drain contact by a dielectric material. The active gate may comprise a high-k dielectric material around a portion of the 2D material; and a gate metal around a portion of the high-k dielectric material. The conductive oxide material may be formed around the dielectric. The 2D material may be an N-type material or a P-type material.

The device may further include a second dielectric extending from a third source/drain contact to a fourth source drain contact; a second conductive oxide material on a portion of the second dielectric; a second 2D material around the second dielectric and extending from the third source/drain contact to the fourth source drain contact; and a second active gate around the second 2D material.

The dielectric, conductive oxide material, 2D material, active gate, first source/drain contact, and second source drain contact may form a first transistor structure. The second dielectric, second conductive oxide material, second 2D material, second active gate, third source/drain contact, and fourth source drain contact may form a second transistor structure. The second transistor structure may be disposed above the first transistor structure and separated by a third dielectric. The 2D material may be an N-type material, and the second 2D material may be a P-type material.

In yet another embodiment, a transistor structure may comprise a source metal; a drain metal; a two-dimensional (2D) channel material around a portion of a seed layer nano-sheet that extends between the source metal and the drain metal; a high-k dielectric around a portion of the 2D channel material; and a gate metal around a portion of the high k-dielectric and isolated from the source metal and the drain metal by a dielectric material.

The source metal and the drain metal may be in contact with a portion of the high-k dielectric. The source metal and the drain metal may be in contact with to the 2D channel material.

These and other aspects and implementations are discussed in detail below. The foregoing information and the following detailed description include illustrative examples of various aspects and implementations, and provide an overview or framework for understanding the nature and character of the claimed aspects and implementations. The drawings provide illustration and a further understanding of the various aspects and implementations, and are incorporated in and constitute a part of this specification. Aspects can be combined and it will be readily appreciated that features described in the context of one aspect of the invention can be combined with other aspects. Aspects can be implemented in any convenient form. As used in the specification and in the claims, the singular form of ‘a’, ‘an’, and ‘the’ include plural referents unless the context clearly dictates otherwise.

### BRIEF DESCRIPTION OF THE DRAWINGS

Non-limiting embodiments of the present disclosure are described by way of example with reference to the accompanying figures, which are schematic and are not intended to be drawn to scale. Unless indicated as representing the background art, the figures represent aspects of the disclosure. For purposes of clarity, not every component may be labeled in every drawing. In the drawings:

FIGS. 1-15 show various views of a first process flow to manufacture semiconductor devices having advanced 3D device architectures using nanosheets with 2D materials, according to an embodiment;

FIGS. 16-18 show various views of a second process flow to manufacture semiconductor devices having advanced 3D device architectures using nanosheets with 2D materials, according to an embodiment;

FIGS. 19-23 show various views of a third process flow to manufacture semiconductor devices having advanced 3D device architectures using nanosheets with 2D materials, according to an embodiment;

FIGS. 24-26 show various views of a fourth process flow to manufacture semiconductor devices having advanced 3D device architectures using nanosheets with 2D materials, according to an embodiment;

FIGS. 27-34 show various views of a fifth process flow to manufacture semiconductor devices having advanced 3D device architectures using nanosheets with 2D materials, including various alternative process steps, according to an embodiment;

FIGS. 35-40 show various views of a sixth process flow to manufacture semiconductor devices having advanced 3D device architectures using nanosheets with 2D materials, according to an embodiment;

FIGS. 41-46 show various views of a seventh process flow to manufacture semiconductor devices having advanced 3D device architectures using nanosheets with 2D materials, according to an embodiment;

FIGS. 47-55 show various views of an eighth process flow to manufacture semiconductor devices having advanced 3D device architectures using nanosheets with 2D materials, according to an embodiment; and

FIGS. 56-58 show flow diagrams of example methods for fabricating devices using the process flows described in connection with FIGS. 1-55, according to an embodiment.

### DETAILED DESCRIPTION

Reference will now be made to the illustrative embodiments depicted in the drawings, and specific language will be used here to describe the same. It will nevertheless be understood that no limitation of the scope of the claims or this disclosure is thereby intended. Alterations and further modifications of the inventive features illustrated herein, and additional applications of the principles of the subject matter illustrated herein, which would occur to one skilled in the relevant art and having possession of this disclosure, are to be considered within the scope of the subject matter disclosed herein. Other embodiments may be used and/or other changes may be made without departing from the spirit or scope of the present disclosure. The illustrative embodiments described in the detailed description are not meant to be limiting of the subject matter presented.

The embodiments described herein enable the formation of semiconductor devices having advanced 3D device architectures using nanosheets with 2D materials. One feature of the semiconductor devices described herein is that the source/drain contacts are clamed to the region forming a channel structure, improving the overall electrical connection and resulting in more robust performance over conventional transistor devices. The present techniques utilize a layer of conductive oxide, which is replaced with a 2D material that behaves as a semiconductor channel. The transistor devices described herein can be defined within a 3D high performance nanosheet, which may include layers of conductive dielectrics integrated with 2D materials for high performance transistors. In some embodiments, conductive oxides can serve as a connection between the source/drain contacts and a 2D material. Additionally, a base substrate of silicon is not required to perform the techniques described herein, allowing the present devices to be formed on any suitable surface or base layer. This also allows for increased 3D stacking of semiconductor devices and allows for a stack of N devices, rather than conventional single-layer devices. The present techniques can be used to create any type of semiconductive device, including NMOS devices, PMOS devices, and CFET devices. The techniques described herein may be implemented utilizing pre-aligned masks to improve etching various layers or openings during device fabrication.

Reference will now be made to the figures, which for the convenience of visualizing the fabrication techniques described herein, illustrate a variety of materials undergoing a process flow in various views. Unless expressly indicated otherwise, each Figure represents one (or a set) of fabrication steps in a process flow for manufacturing the devices described herein. In the various views of the Figures, connections between conductive layers or materials may or may not be shown. However, it should be understood that connections between various layers, masks, or materials may be implemented in any configuration to create electric or electronic circuits. When such connections are shown, it should be understood that such connections are merely illustrative, and are intended to show a capability for providing such connections, and should not be considered limiting to the scope of the claims.

Likewise, although the Figures and aspects of the disclosure may show or describe devices herein as having a particular shape, it should be understood that such shapes are merely illustrative and should not be considered limiting to the scope of the techniques described herein. For example, the techniques described herein may be implemented in any shape or geometry for any material or layer to achieve desired results. In addition, examples in which two transistors or devices are shown stacked on top of one another are shown for illustrative purposes only, and for the purposes of simplicity. Indeed, the techniques described herein may provide for one to any number of stacked devices. Further, although the devices fabricated using these techniques are shown as transistors, it should be understood that any type of electric electronic device may be manufactured using such techniques, including but not limited to transistors, variable resistors, resistors, and capacitors.

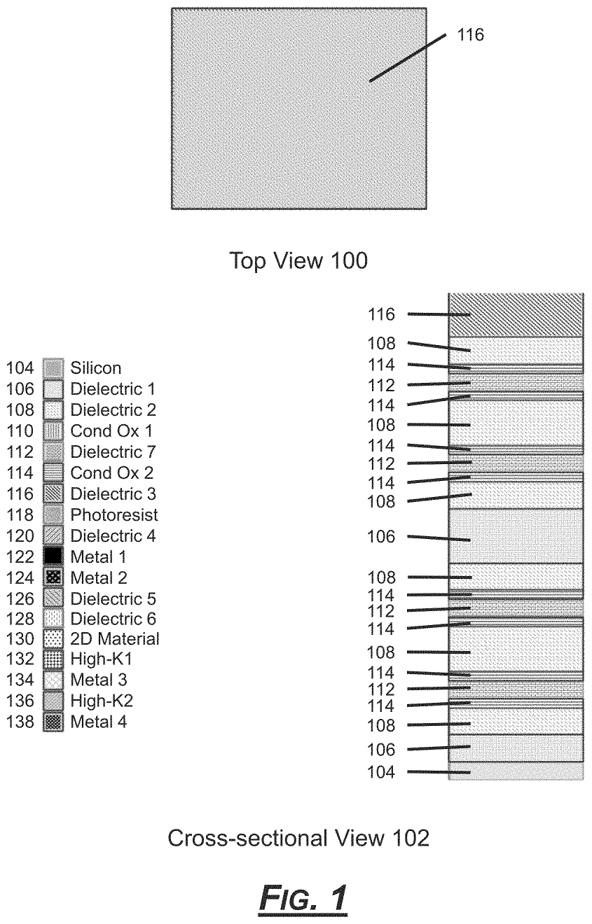

FIGS. 1-15 show various views of a first process flow to manufacture semiconductor devices having advanced 3D device architectures using nanosheets with 2D materials. Each of the FIGS. 1-15 generally refer to one or more process steps in a process flow, each of which are described in detail in connection with a respective Figure. For the purposes of simplicity and ease of visualization, some reference numbers may be omitted from some Figures. Referring to FIG. 1, illustrated is a top view 100 and a cross-sectional view 102 of a base structure, shown here as a stack of layers. The stack of layers may be formed on a base layer 104 (shown as “Silicon” in the legend), which may be any type of base material, including other stacks of layers formed using processes similar to those described herein. To form the stack of layers, a first layer of dielectric material 106 (shown in the legend as the “Dielectric 1”) is formed on the base layer 104, and a first layer of a second dielectric material 108 (shown as “Dielectric 2” in the legend) is formed on top of the layer of dielectric material 106. The layers may be formed using any suitable material deposition or formation technique, including, for example, atomic layer deposition (ALD), chemical vapor deposition (CVD), physical vapor deposition (PVD), plasma-enhanced CVD (PECVD), or epitaxial growth, among others.

As used herein, the terms “first,” “second,” “third,” and “fourth” with respect to particular layers of the stack shown in FIGS. 1-15 refer to the order of the layers relative to the base layer 104. For example, a “first” layer of a particular material refers to the specified type of layer which is closest to the base layer 104. Likewise, a “second” layer of a particular material refers to the specified type of layer which is second closest to the base layer 104, and so on. The dielectric material 106 and the second dielectric material 108 can be any type of dielectric material, including but not limited to oxide materials. The dielectric material 106 and the second dielectric material 108 can operate as electric insulators. A layer of a first semiconductive-behaving material 114 (shown in the legend as “Cond Ox 2”) can be formed on the second dielectric material 108. The semiconductive-behaving material 114 can be, for example, conductive oxide materials (sometimes referred to herein as “conductive channels” or “conductive oxides”), which may have similar properties to semiconductor materials. Certain materials, when combined with oxygen, may form new materials that exhibit semiconductor properties (e.g., features formed with the materials can turn “off” with low off-state leakage current, or can become highly conductive under certain circumstances, etc.). Some examples of N-type conductive oxides include In₂O₃, SnO₂, InGaZnO, and ZnO. One example of a P-type conductive oxide is SnO. One example of a P-type conductive channel is SnO.

A layer of third dielectric material 112 (shown in the legend as “Dielectric 7”) can then be deposited on the first layer of the semiconductive-behaving material 114, and a second layer of the semiconductive-behaving material 114 can be formed on the layer of the third dielectric material 112. The third dielectric material 112 can be any type of dielectric material, such as an oxide material. A second layer of the second dielectric material 108 can then be formed on the second layer of the semiconductive-behaving material 114. Then, a similar pattern of layers of the third dielectric material 112 and the semiconductive-behaving material 114 can be formed. This creates two layers of the third dielectric material 112, each sandwiched between two layers of the semiconductive-behaving material 114, in the bottom half of the device. To separate the bottom half of the device from the top half of the device, alternating layers of the second dielectric material 108 and the first dielectric material 106 (which may be thicker than other layers in the stack to provide additional isolation between transistor structures) can be formed in the middle of the device. Additional layers of semiconductive behaving material 114 sandwiching layers of the third dielectric material 112 can be formed to define additional transistor structures in the stack of materials. Once the desired number of transistor structures have been defined in the stack of layers (e.g., isolated from one another by layers of the second dielectric material 108, as shown in the cross-sectional view 102), a top layer of a fourth dielectric material 116 (shown as the “Dielectric 3” in the legend) can be formed using a suitable material deposition technique.

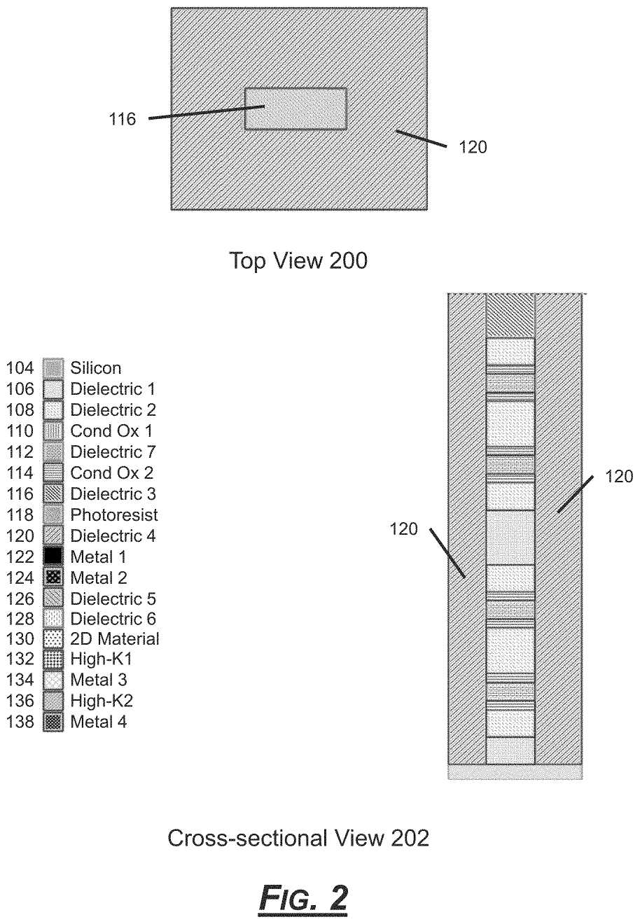

Referring to FIG. 2, illustrated are a top view 200 and a cross-sectional view 202 of the next stage in the process flow. At this stage in the process flow, the stack of layers formed on the base layer 104 can be etched to a desired width and length, as shown in the top view 200. Although the stack of layers has been etched in a rectangle shape, it should be understood that the stack of layers can be formed in any desired geometry. The width or length can be chosen based on desired electrical characteristics of the device. Any suitable etching or material removal technique can be used, including but not limited to dry etching, wet etching, or plasma etching techniques, among others. A nanosheet mask may be used to pattern the stack of layers. The etching process may have an etch stop at the base layer 104. After etching the stack of layers, a fifth dielectric material 120 (shown in the legend as “Dielectric 4”) can be deposited around the stack of layers using any suitable material deposition technique, as shown in the top view 200 and the cross-sectional view 202. While these figures illustrate a single defined device area for the sake of simplicity, this area may be surrounded by an insulating material and may be one of many such structures spanning in the x- and y-directions, insulated from each other by the fifth dielectric material 120.

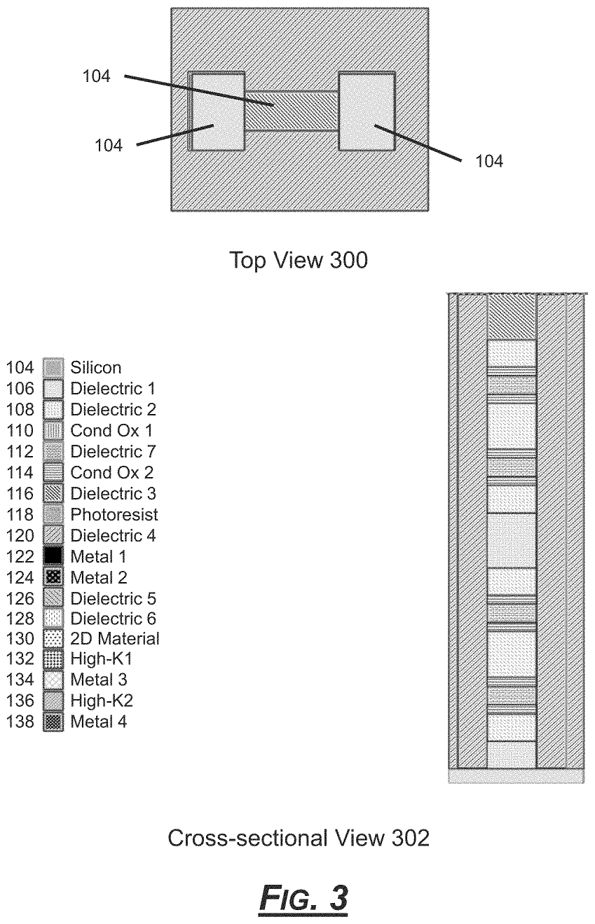

Referring to FIG. 3, illustrated are a top view 300 and a cross-sectional view 302 of the next stage in the process flow. At this stage in the process flow, one or more openings (sometimes referred to herein as the “source/drain openings”) can be formed through the fifth dielectric material 120, adjacent to one or more corresponding sides of the now-etched stack of layers. The openings can define the regions that will be occupied by metal contacts that form the source/drain of one or more transistor structures formed using the present techniques. The openings can be defined using a nanosheet mask over the top of the fifth dielectric material 120. Any suitable etching or material removal technique can be used, including but not limited to dry etching, wet etching, or plasma etching techniques, among others. Although two openings are shown here, it should be understood that any number of openings can be formed through the fifth dielectric material 120 for use in further process steps.

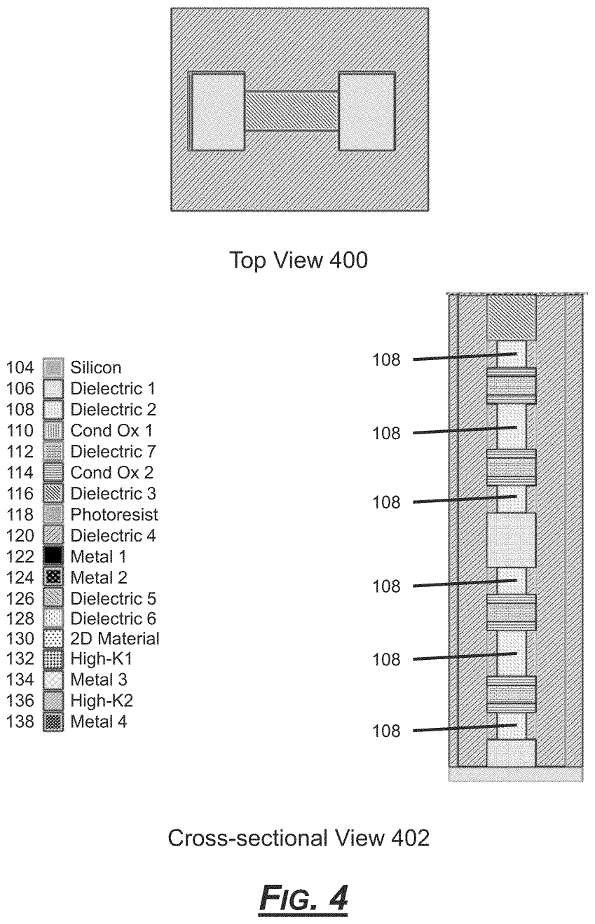

Referring to FIG. 4, illustrated are a top view 400 and a cross-sectional view 402 of the next stage in the process flow. At this stage in the process flow, the second dielectric material 108 can be etched partially via the source/drain openings formed in the previous stage. The etching process used is considered a recess etch and may be a selective etching process, which leaves the other layers and other materials shown in FIG. 4 intact while partially etching the second dielectric material 108. However, in some implementations, a protective layer may be selectively deposited over the other layers in the stack of layers to protect those layers from the etching process used to recess the second dielectric material 108. The protective layer can then be removed prior to performing further process steps. Etching the second dielectric material 108 can create one or more recessed air gaps in the regions previously occupied by the second dielectric material 108. The new length (e.g., from left to right in the cross-sectional view 402) of the second dielectric material 108 can define the length of the active gate materials when formed in layer process steps. Therefore, etching the second dielectric material 108 in this manner can isolate metal contacts for the source/drain from the gate metal, as will be described in greater detail herein.

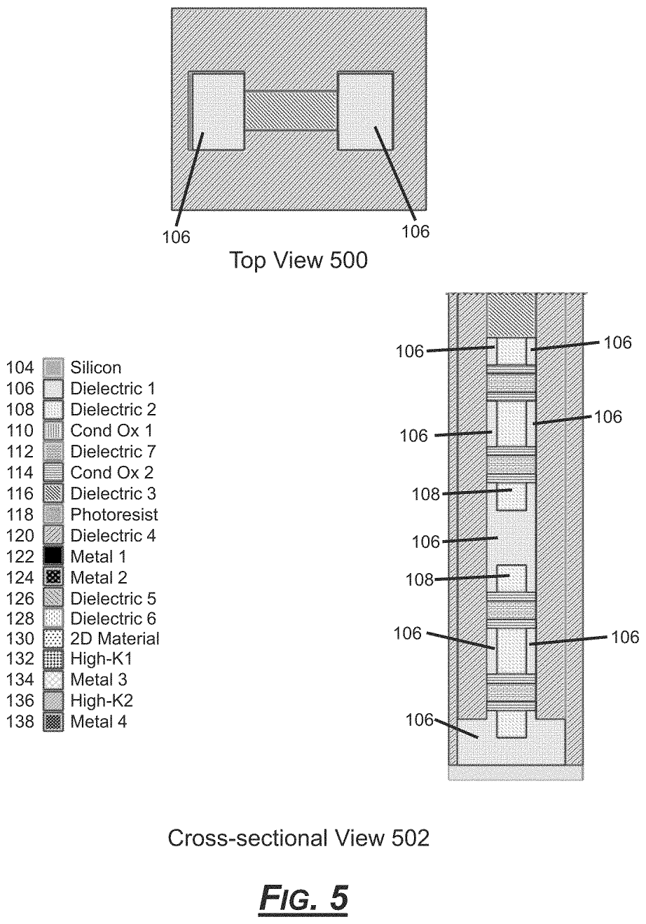

Referring to FIG. 5, illustrated is a top view 500 and a cross-sectional view 502 of the next stage in the process flow. At this stage in the process flow, the source/drain openings and the recessed air gaps formed by etching the second dielectric material 108 can be deposit-filled with the first dielectric material 106. In some implementations, a chemical-mechanical polish (CMP) process may be performed after depositing the first dielectric material 106. Then, the first dielectric material 106 can be directionally etched until it is level with the bottom of the first layer of the second dielectric material 108, as shown in the cross-sectional view 502. Etching the first dielectric material 106 re-exposes the sides of the stack of layers (including the semiconductive-behaving material 114 and the third dielectric material 112) in the openings, while isolating the openings from the base layer 104. The first dielectric material 106 is directionally etched such that the recessed air gaps formed when etching the second dielectric material 108 are now filled with the first dielectric material 106. In some implementations, the first dielectric material 106 can be directionally etched such that the base layer 104 is exposed in the openings.

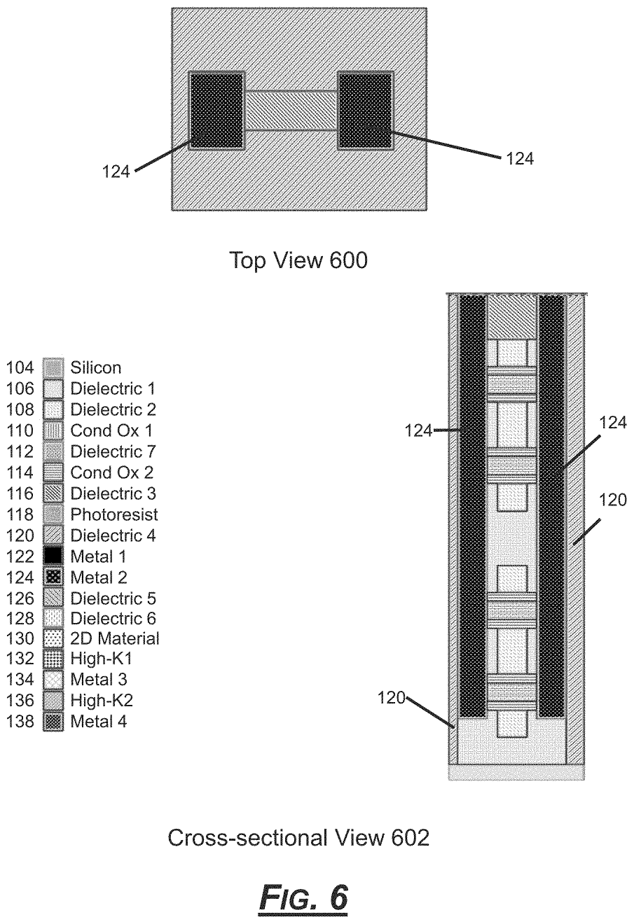

Referring to FIG. 6, illustrated is a top view 600 and a cross-sectional view 602 of the next stage in the process flow. At this stage in the process flow, the source/drain openings can be deposit-filled with a metal material 124 (shown in the legend as “Metal 2” and sometimes referred to herein as the “source/drain metal” or the “source/drain contact”). Any suitable material deposition technique may be used to deposit fill the openings with the metal material 124. In some implementations, a chemical-mechanical polish (CMP) process may be performed after depositing the metal material 124. Alternatively, the metal material 124 can be grown on one or more of the materials exposed in the openings. For example, the metal material 124 may be grown on the semiconductive-behaving material 114. If the base layer 104 is exposed, and the base layer 104 is made of a doped silicon material, the metal material 124 may be epitaxially grown on the base layer 104 such that it fills the openings. In some implementations, the metal material 124 may be grown on both the semiconductive-behaving material 114 and the base layer 104.

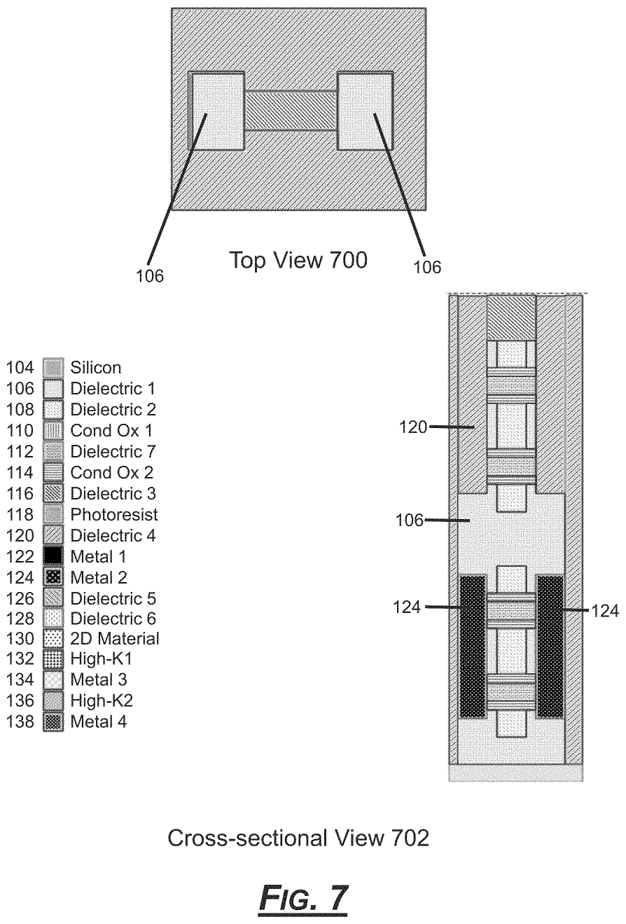

Referring to FIG. 7, illustrated is a top view 700 and a cross-sectional view 702 of the next stage in the process flow. At this stage in the process flow, the metal material 124 can be directionally etched until it is level with the bottom of the first layer of the second dielectric material 108, as shown in the cross-sectional view 702. Etching the metal material 124 can allow two bottom transistor structures formed in later process steps to be electrically isolated from two top transistors formed in later process steps. However, it should be understood that alternative approaches are also possible. For example, the metal material 124 may be etched such that it contacts the top layer of the semiconductive-behaving material 114 in the bottom half of the device. Then, a layer of the first dielectric material 106 may be deposited and etched until just below the first layer of the semiconductive-behaving material 114 in the top half of the device, as shown. The first dielectric material 106 deposited in the source/drain openings can isolate the transistor structures in the bottom half of the device from those in the top half of the device.

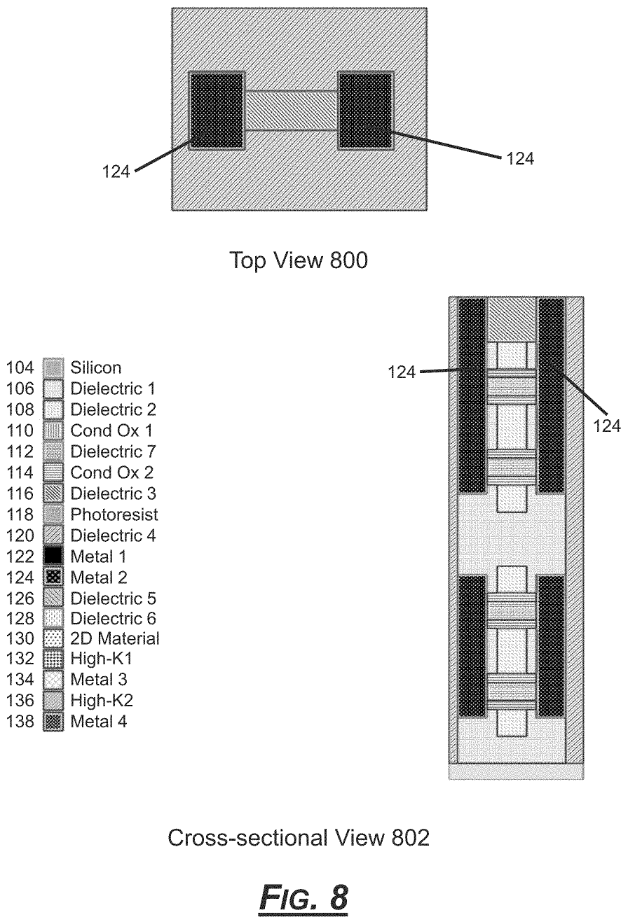

Referring to FIG. 8, illustrated is a top view 800 and a cross-sectional view 802 of the next stage in the process flow. At this stage in the process flow, the openings above the now-etched first dielectric material 106 can be deposit-filled with the metal material 124. Any suitable material deposition technique may be used to deposit fill the openings with the metal material 124. In some implementations, a CMP process may be performed after depositing the metal material 124. Alternatively, the metal material 124 can be grown on one or more of the materials exposed in the openings. For example, the metal material 124 may be grown on the semiconductive-behaving material 114 or on the third dielectric material 112.

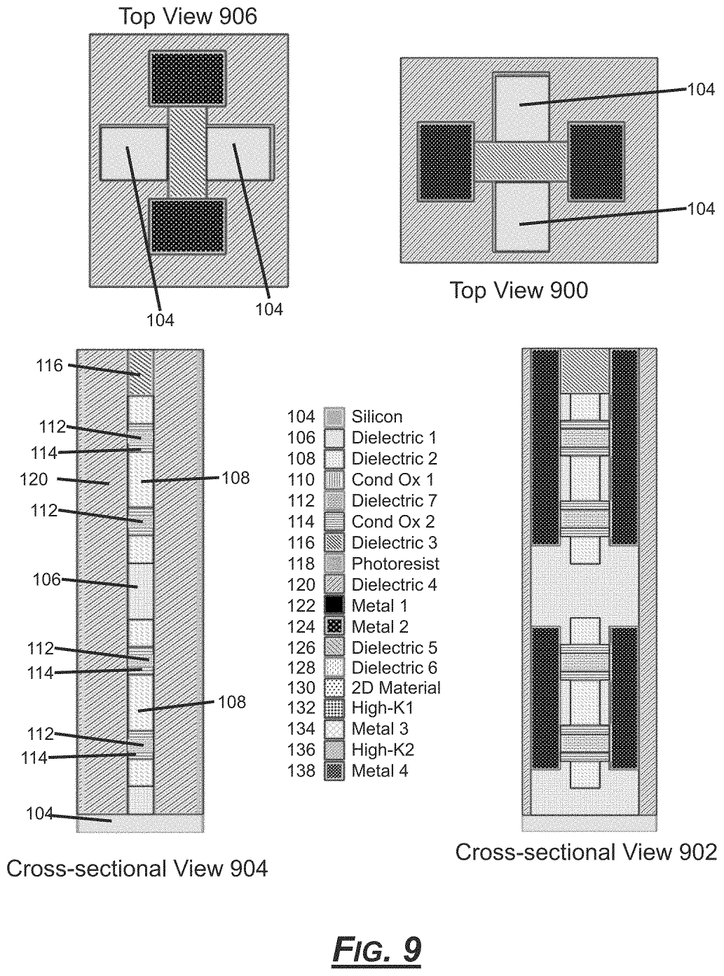

Referring to FIG. 9, illustrated are top views 900 and 906 and cross-sectional views 902 and 904 of the next stage in the process flow. At this stage in the process flow, one or more gate openings can be formed through the fifth dielectric material 120, adjacent to one or more corresponding sides of the stack of layers, different from the sides adjacent to the openings that were used to form the source/drain contacts with the metal material 124. The gate openings can define the regions that will be occupied by the gate materials, including the gate metals, gate dielectric materials, and other materials, for transistor structures formed using the present techniques. The length of the gate openings can match the length of the second dielectric material 108. The gate openings can be defined using a nanosheet mask over the top of the fifth dielectric material 120. Any suitable etching or material removal technique can be used, including but not limited to dry etching, wet etching, or plasma etching techniques, among others, to etch the fifth dielectric material 120.

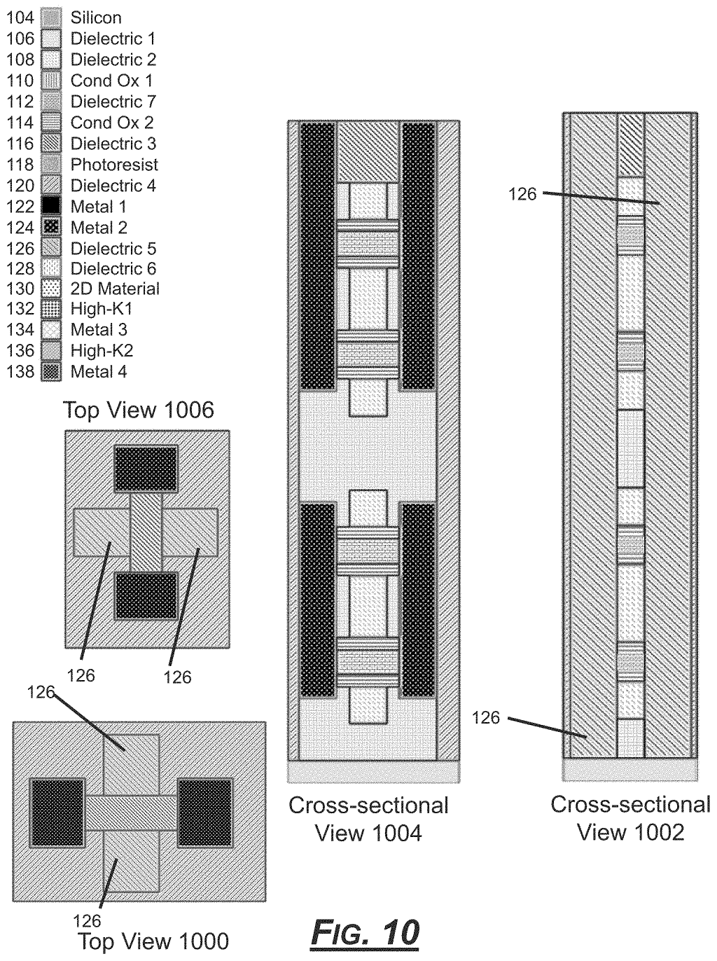

Referring to FIG. 10, illustrated are top views 1000 and 1006 and cross-sectional views 1002 and 1004 of the next stage in the process flow. At this stage in the process flow, the gate openings etched through the fifth dielectric material 120 can be deposit-filled with a sixth dielectric material 126 (shown in the legend as “Dielectric 5”). In some implementations, a CMP process may be performed after depositing the sixth dielectric material 126. Any suitable material deposition technique can be used to deposit the sixth dielectric material 126, including ALD, CVD, PVD, or PECVD, among others. Depositing the sixth dielectric material 126 can protect the gate region and form a dummy (or placeholder) material where a gate will later be formed.

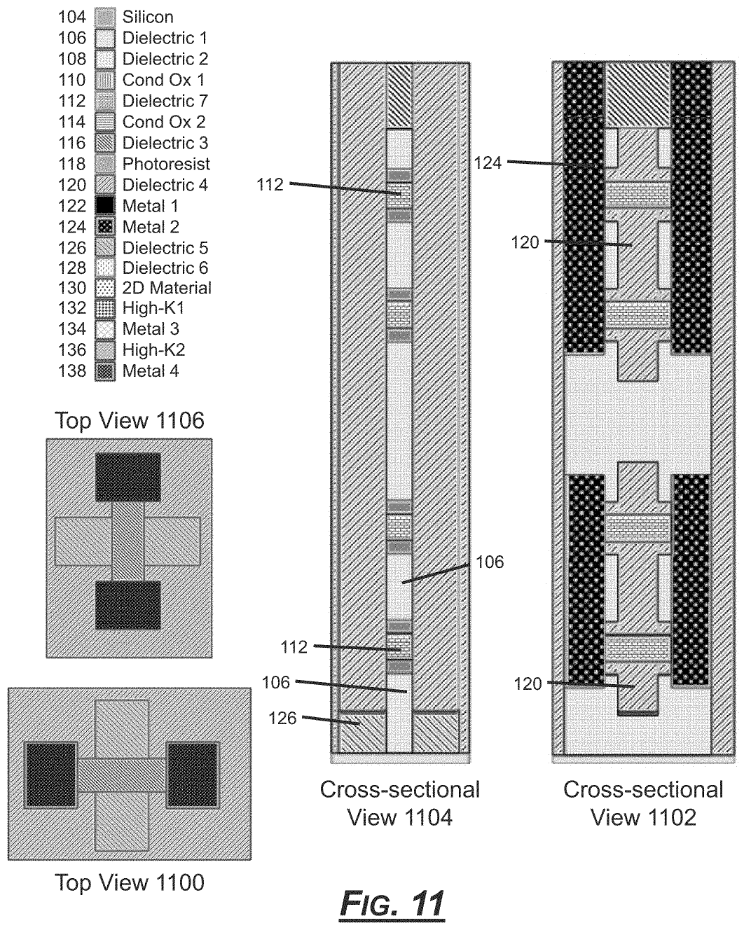

Referring to FIG. 11, illustrated are top views 1100 and 1106 and cross-sectional views 1102 and 1104 of the next stage in the process flow. At this stage in the process flow, the fifth dielectric material 126 can be directionally etched until all layers of the semiconductive-behaving material 122 are exposed in the gate openings. The sixth dielectric material 126 can be etched such that the base layer 104 is not exposed in the gate openings, effectively isolating the base layer 104 from any gate materials. Additionally, as shown, the second dielectric material 108 and the semiconductive-behaving materials 114 can be removed using an etching process. The third dielectric material 112 layers can be held in place between the columns of the metal material 124. This allows gate materials, such as gate dielectric materials and gate metal materials, to be formed to completely surround portions of the gate.

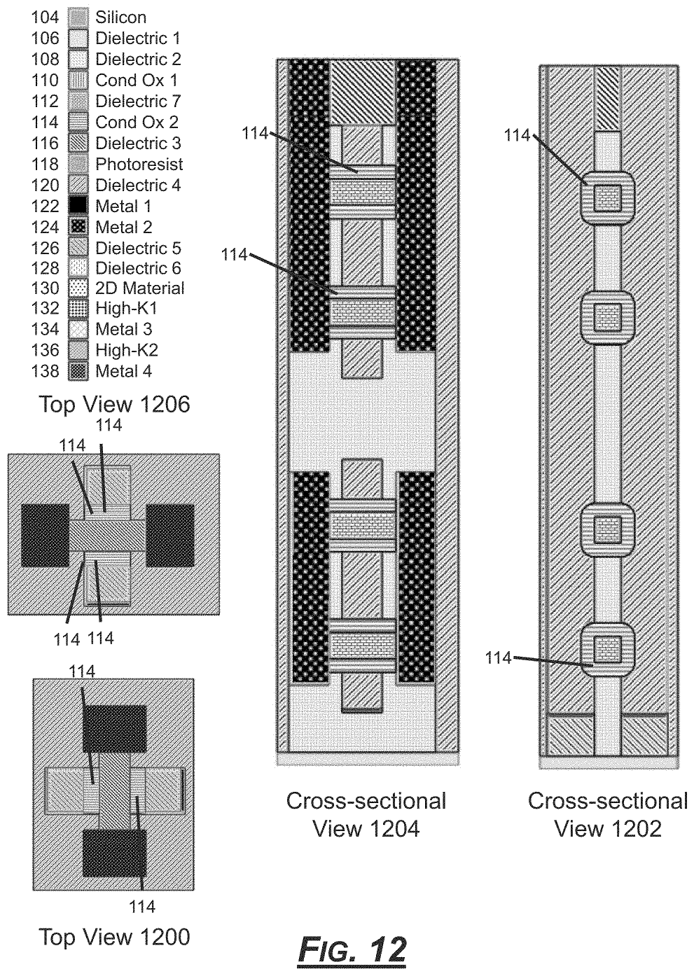

Referring to FIG. 12, illustrated are top views 1200 and 1206 and cross-sectional views 1202 and 1204 of the next stage in the process flow. At this stage in the process flow, the semiconductive-behaving material 114 can be re-deposited on the layers of the third dielectric material 114, via the one or more gate openings. The semiconductive-behaving material 114 can be selectively deposited or selectively grown on the third dielectric material 112. As shown in the cross-sectional view 1204, the semiconductive-behaving material 114 can be formed to surround the third dielectric material 112 in the gate openings. The semiconductive-behaving material 114 may contact a portion of the metal material 124. In some implementations, the semiconductive-behaving material 114 may be selectively deposited on just the third dielectric material 112 of the bottom or the top of the layers, for example, by shielding some of the layers of the semiconductive-behaving material 114 in the gate openings with a thin layer of another dielectric material.

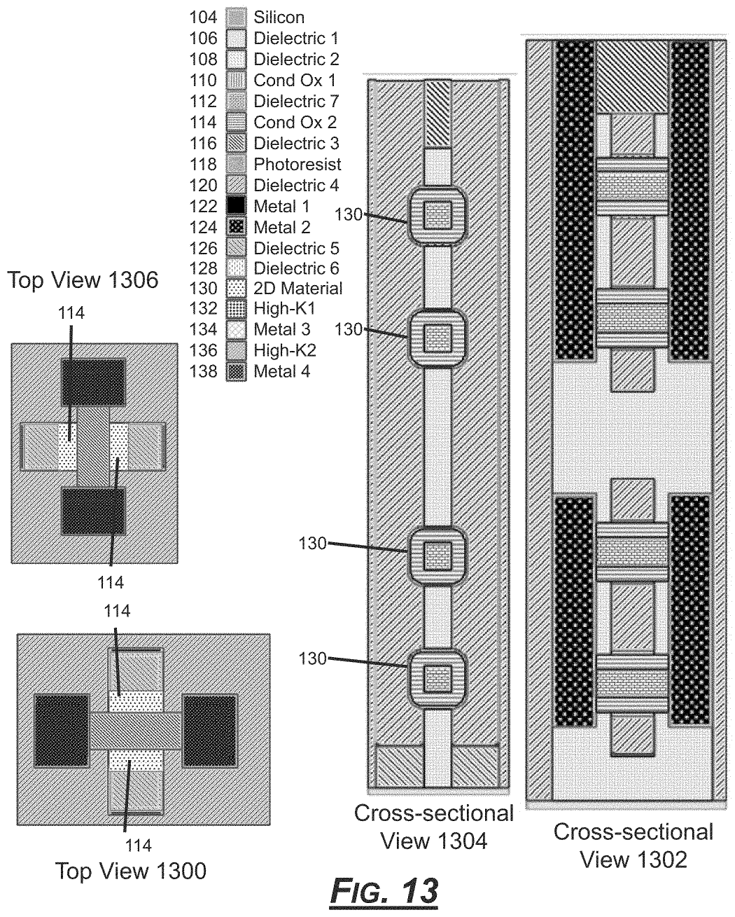

Referring to FIG. 13, illustrated are top views 1300 and 1306 and cross-sectional views 1302 and 1304 of the next stage in the process flow. At this stage in the process flow a 2D material 130 (shown in the legend as “2D material”) can be formed on the semiconductive-behaving material 114. The 2D material 130 can be formed to surround the layer of the semiconductive-behaving material 114 in the gate openings. The 2D material 130 can be any type of suitable material including transition-metal dichalcogenide (TMD) materials such as WS₂, WSe₂, WTe₂, MoS₂, MoSe₂, MoTe₂, HfS₂, ZrS₂, TiS₂, GaSe, InSe, InGaZrO, graphene or phosphorene, among others. These materials may be 5-15 angstroms thick, the thinness lending to their name—2D material. The 2D material 130 can be selectively deposited on the semiconductive-behaving material 114. The 2D material 130 can be deposited using any suitable material deposition technique, including ALD, CVD, PVD, or PECVD, among others. In some implementations, the 2D material 130 can be selectively grown on the semiconductive-behaving material 114, such that the semiconductive-behaving material 114 behaves as a seed material. The materials may be annealed during or after the device formation process to recrystallize or grow the crystals and thereby improve electrical characteristics. For the sake of simplicity, the use of conductive dielectrics will be disclosed.

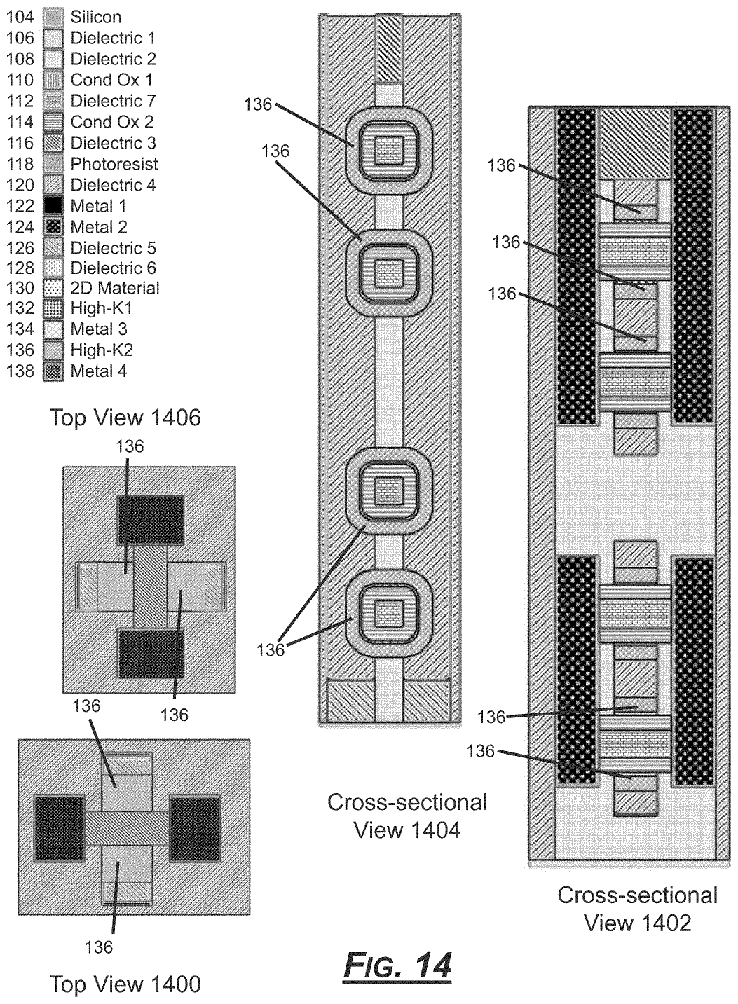

Referring to FIG. 14, illustrated are top views 1400 and 1406 and cross-sectional views 1402 and 1404 of the next stage in the process flow. At this stage in the process flow, a high-k dielectric material 136 (shown as “High-K2” in the legend) can be selectively deposited on the 2D material 130 via the gate opening. The high-k dielectric material 136 acts as a gate dielectric material for the channel formed from the 2D material 130 and the semiconductive-behaving material 130, which is defined by the 2D material 130. The high-k dielectric material 136 can be any type of material with a relatively high dielectric constant and may be deposited at a predetermined thickness to achieve a desired capacitance. In some implementations, the high-k dielectric material 136 can be selectively deposited or grown, such that the high-k dielectric is deposited only on the 2D material 130. The high-k dielectric material 136 may be deposited using any suitable material deposition technique, including but not limited to ALD, CVD, PVD, or PECVD, among others.

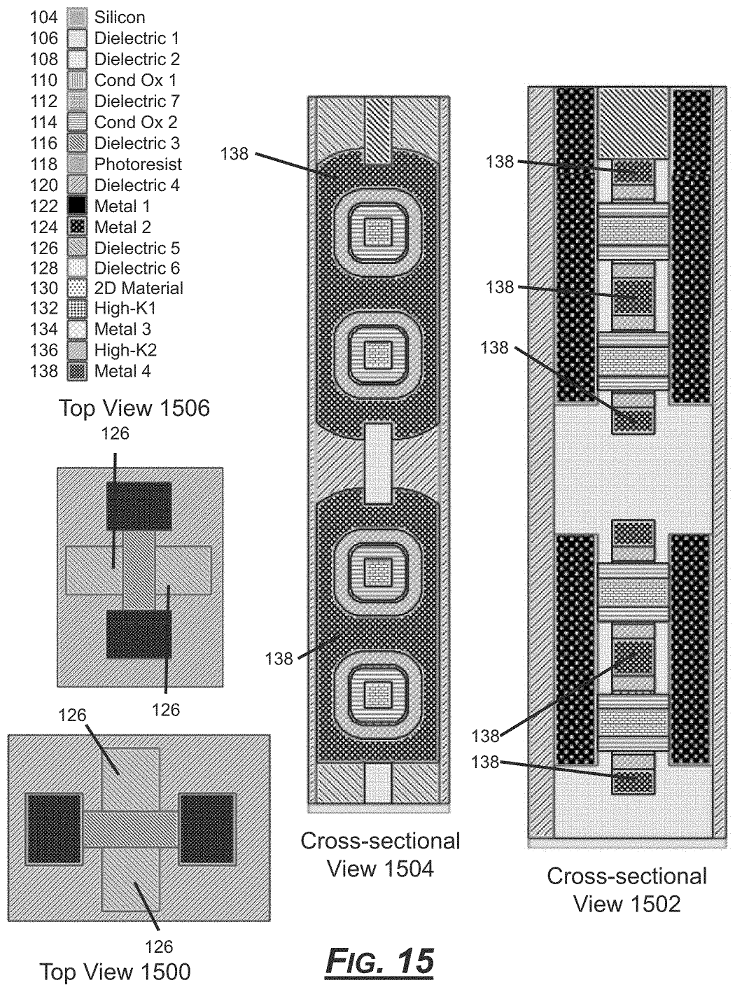

Referring to FIG. 15, illustrated are top views 1500 and 1506 and cross-sectional views 1502 and 1504 of the next stage in the process flow. At this stage in the process flow, a gate metal 138 (shown in the legend as “Metal 4”) can be selectively formed on the high-k dielectric material 136. The gate metal 138 may be deposited using any suitable material deposition technique, including but not limited to ALD, CVD, PVD, or PECVD, among others. In some implementations, the gate metal 138 may be grown on the high-k dielectric material 136, such that the high-k dielectric material 136 behaves as a seed material for the gate metal 138. As shown, two regions of the gate metal 138 can be formed, each of which surround the pair of bottom and the pair of top transistor structures. In the configuration shown in cross-sectional view 1402, the gate metal 138 is shaped like a numeral “8,” whereby the gate metal 138 is rectangular, rectangular with curved ends, or stadium-shaped, and the gate metal 138 has two apertures filed by the conductive oxide channel, 2D material, and high-k dielectric. Although the gate metal 138 is shown here as completely surrounding both bottom transistor structures, it should be understood that temporary dielectric layers, etching, or other techniques may be used to isolate the gate metal 138 for each transistor from one another. As shown in the cross-sectional view 1402, there remains an air gap between the bottom region of the gate metal 138 and the top region of the gate metal 138. Once the gate metal 138 is selectively deposited on the high-k dielectric material 136, the sixth dielectric material 126 can be deposited to fill the remaining space at the top of the gap openings. After depositing the sixth dielectric material 126, a CMP process can be performed.

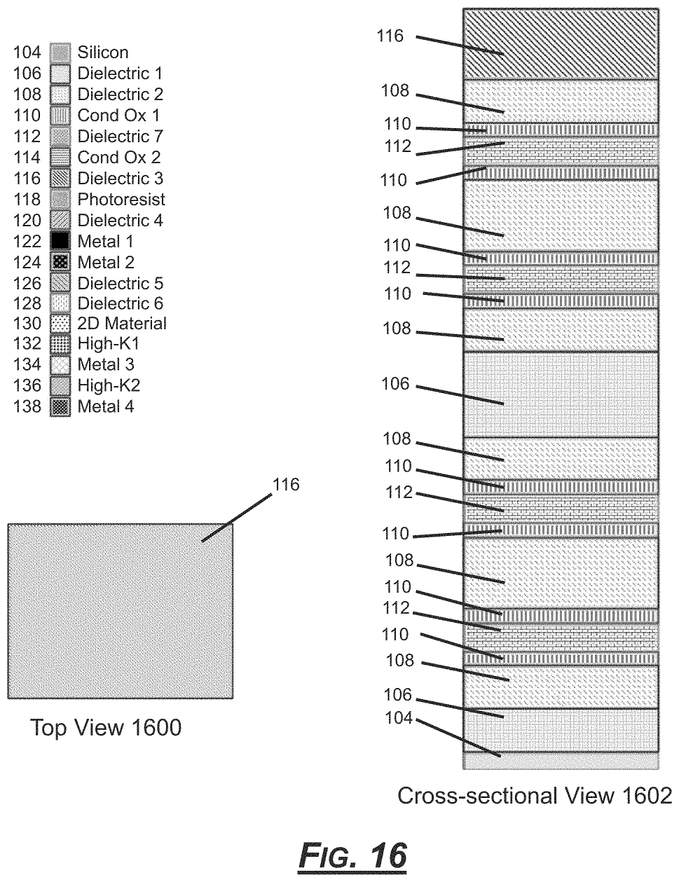

FIGS. 16-18 show various views of a second process flow to manufacture semiconductor devices having advanced 3D device architectures using nanosheets with 2D materials. Each of the FIGS. 16-18 generally refer to one or more process steps in a process flow, each of which are described in detail in connection with a respective Figure. For the purposes of simplicity and ease of visualization, some reference numbers may be omitted from some Figures. FIGS. 16-18 show process steps similar to those described above in connection with FIGS. 1-15, but with alternative materials. The alternative materials may be selected based on a desired polarity of the transistor structures. For example, the materials selected for the process flow described in connection with FIGS. 1-15 may create N-type transistor devices, while the alternative materials selected for the process flow of FIGS. 16-18 may create P-type transistor devices. Referring to FIG. 16, illustrated is a top view 1600 and a cross-sectional view 1602 of the stack of layers. The stack of layers in FIG. 16 can be similar to that described in connection with FIG. 1, but using a second semiconductive-behaving material 110 (shown in the legend as “Cond Ox 1”), rather than the semiconductive-behaving material 114. The second semiconductive-behaving material 110 may be an opposite polarity to the semiconductive-behaving material 114 (e.g., N-type or P-type).

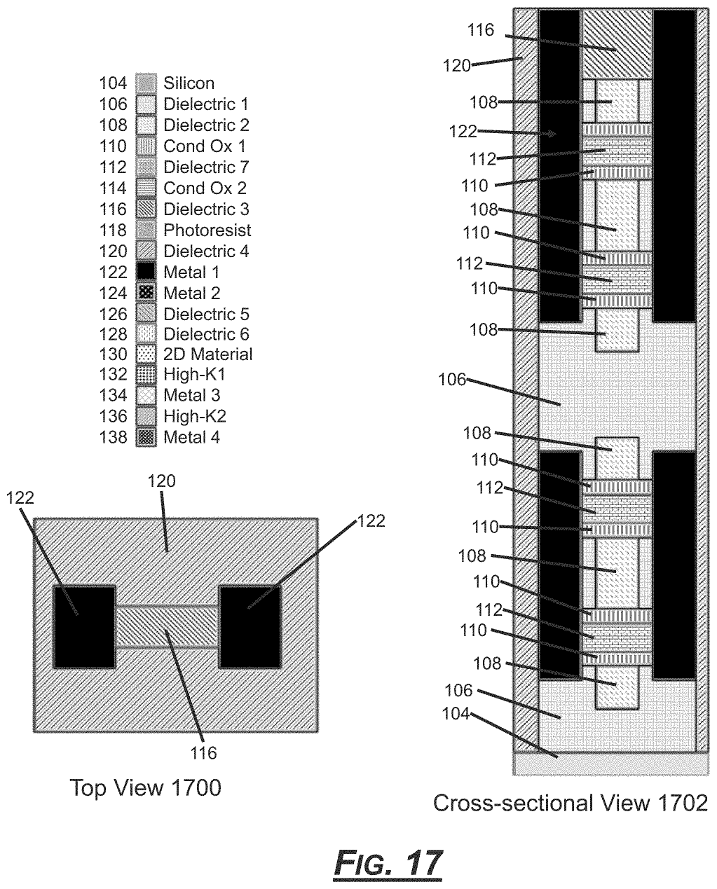

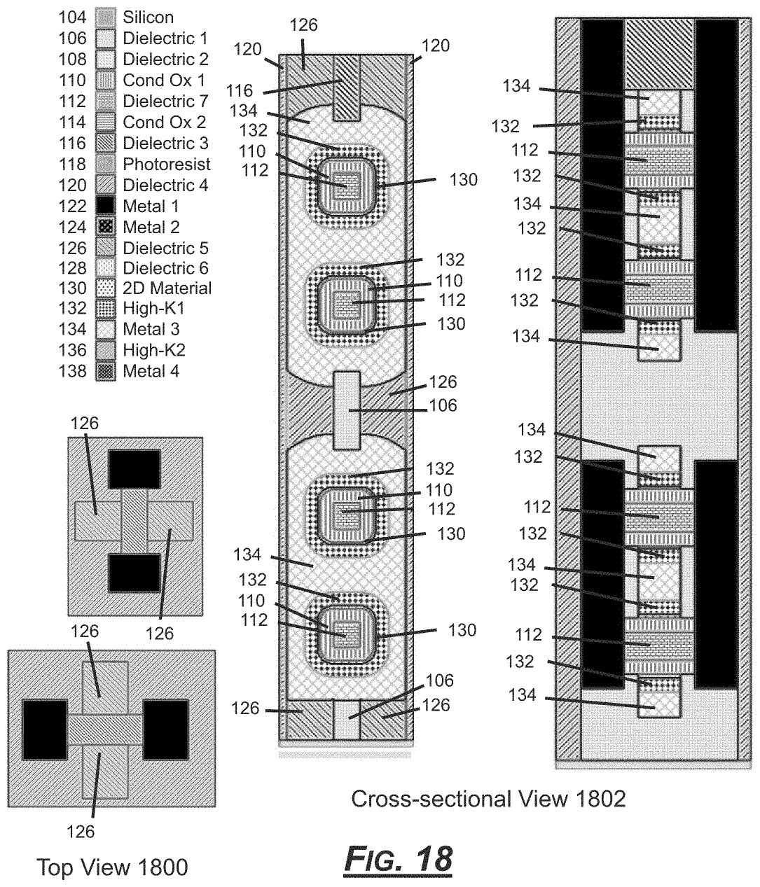

Referring to FIG. 17, illustrated is a top view 1700 and a cross-sectional view 1702 of the next stage in the process flow. At this stage in the process flow, steps similar to those described in connection with FIGS. 2-8 can be performed, but using a second source/drain metal 122 (shown in the legend as “Metal 1”) rather than the source/drain metal 124. Referring to FIG. 18, illustrated is a top view 1800 and a cross-sectional view 1802 of the next stage in the process flow. At this stage in the process flow, steps similar to those described in connection with FIGS. 9-15 can be performed. However, rather than forming the semiconductive behaving material 114, the high-k dielectric material 136, and the gate metal 138, alternative materials can be used, shown here as the second semiconductive-behaving material 110, a second high-k dielectric material 132 (shown in the legend as “High-K 1”), and a second gate metal 134 (shown in the legend as “Metal 3”). These materials may be selected based on the polarity of the 2D material 130, which in this process flow may be the opposite polarity of the 2D material formed in the process flow described in connection with FIGS. 1-15.

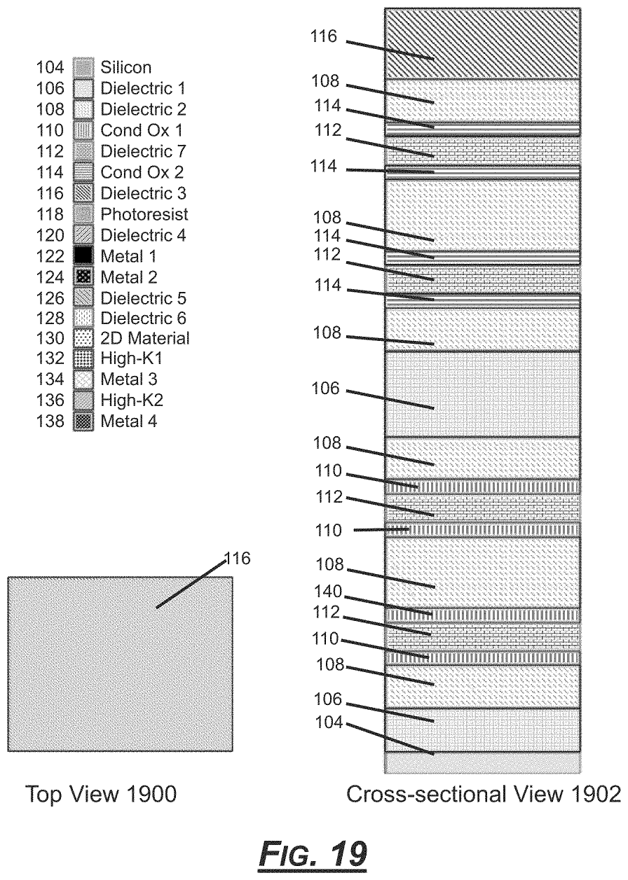

FIGS. 19-23 show various views of a third process flow to manufacture semiconductor devices having advanced 3D device architectures using nanosheets with 2D materials. Each of the FIGS. 19-23 generally refer to one or more process steps in a process flow, each of which are described in detail in connection with a respective Figure. For the purposes of simplicity and ease of visualization, some reference numbers may be omitted from some Figures. FIGS. 19-23 show process steps similar to those described above in connection with FIGS. 1-15, but two of the transistor structures (here, shown as the bottom two transistor structures) are formed using the alternative materials described in connection with FIGS. 16-18. Referring to FIG. 19, illustrated is a top view 1900 and a cross-sectional view 1902 of the stack of layers. The stack of layers in FIG. 19 can be similar to that described in connection with FIG. 1, but using the second semiconductive-behaving material 110 for the bottom two transistor structures and the semiconductive-behaving material 114 for the top two transistor structures. The second semiconductive-behaving material 110 may be an opposite polarity to the semiconductive-behaving material 114 (e.g., N-type or P-type).

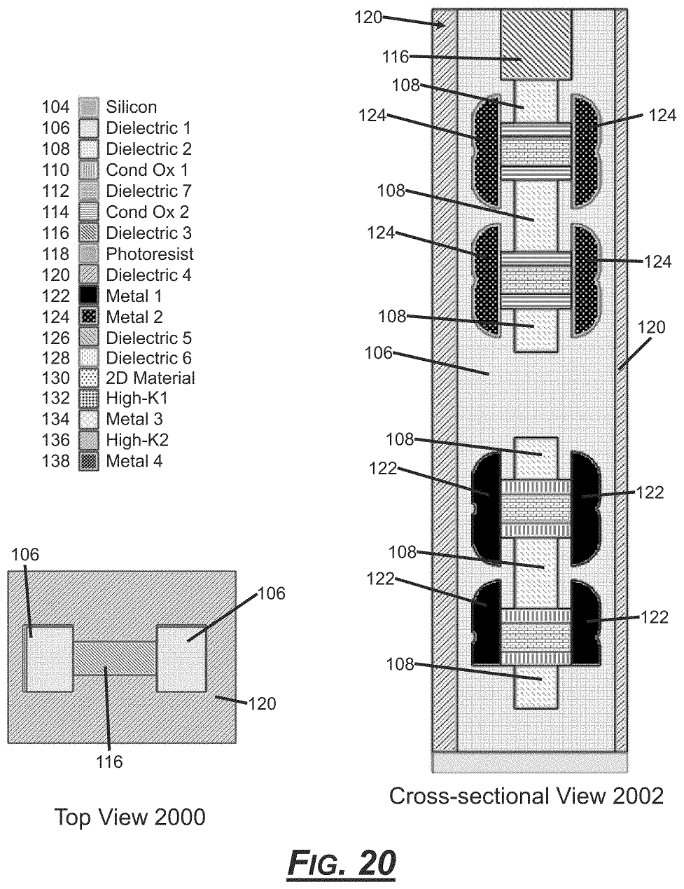

Referring to FIG. 20, illustrated is a top view 2000 and a cross-sectional view 2002 of the next stage in the process flow. At this stage in the process flow, steps similar to those described in connection with FIGS. 2-8 can be performed. As shown, the second source/drain metal 122 is selectively formed on the second semiconductive-behaving material 110, and the source/drain metal 124 is selectively formed on the semiconductive-behaving material 114. The first dielectric material 116 may then be deposited in the source/drain openings to fill any remaining gaps, and a CMP process may be performed. The second source/drain metal 122 and the source/drain metal 124 may be selectively formed or selectively grown using any suitable material formation process.

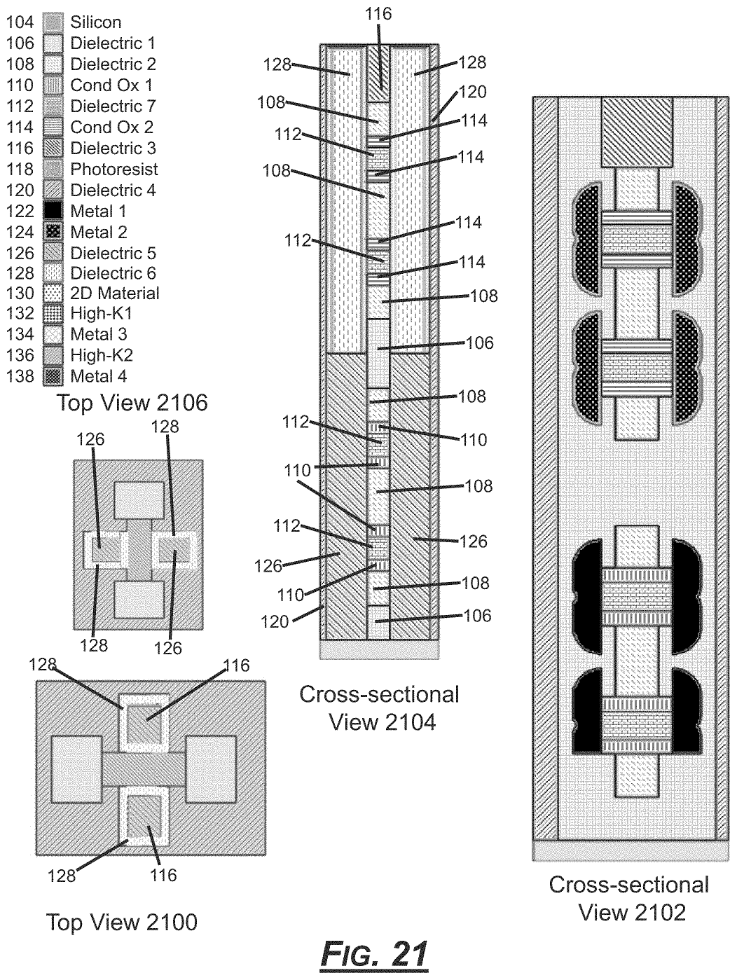

Referring to FIG. 21, illustrated are top views 2100 and 2106 and cross-sectional views 2102 and 2104 of the next stage in the process flow. At this stage in the process flow, process steps similar to those described in connection with FIGS. 9-11, however rather than etching the sixth dielectric material 126 to the bottom of the device, the sixth dielectric material 126 can be etched halfway down the stack of layers, such that the top two transistor structures are exposed in the gate openings. Then, a thin layer of a seventh dielectric material 128 (shown in the legend as “Dielectric 6”) can be formed in the gate layers using any suitable material deposition technique, including ALD, CVD, PVD, PECVD, or epitaxial techniques, among others. The seventh dielectric material 128 can then be directionally etched to expose the sixth dielectric material 126 in the gate openings, as shown in the top views 2100 and 2106.

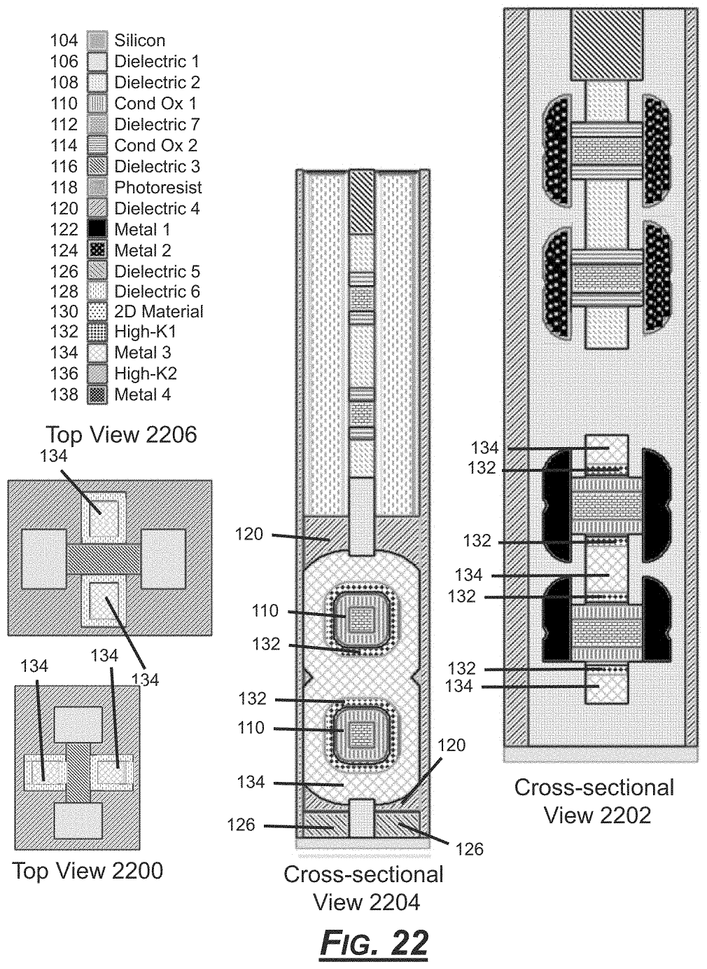

Referring to FIG. 22, illustrated are top views 2200 and 2206 and cross-sectional views 2202 and 2204 of the next stage in the process flow. At this stage in the process flow, process steps similar to those described in connection with FIG. 18 can be performed to form the second semiconductive-behaving material, the 2D material 130, and the alternative active gate (e.g., the second high-k dielectric material 132 and the second gate metal 134) on the bottom transistor structures. The 2D material 130 deposited on the bottom transistor structures may be a P-type material, for example, while the 2D material 130 deposited on the top transistor structures (in later process steps) may be an N-type material. As shown, the seventh dielectric material 128 can protect the layers of material exposed in the gate openings at the top half of the device from the selective deposition techniques used to form the transistor structures at the bottom half of the device.

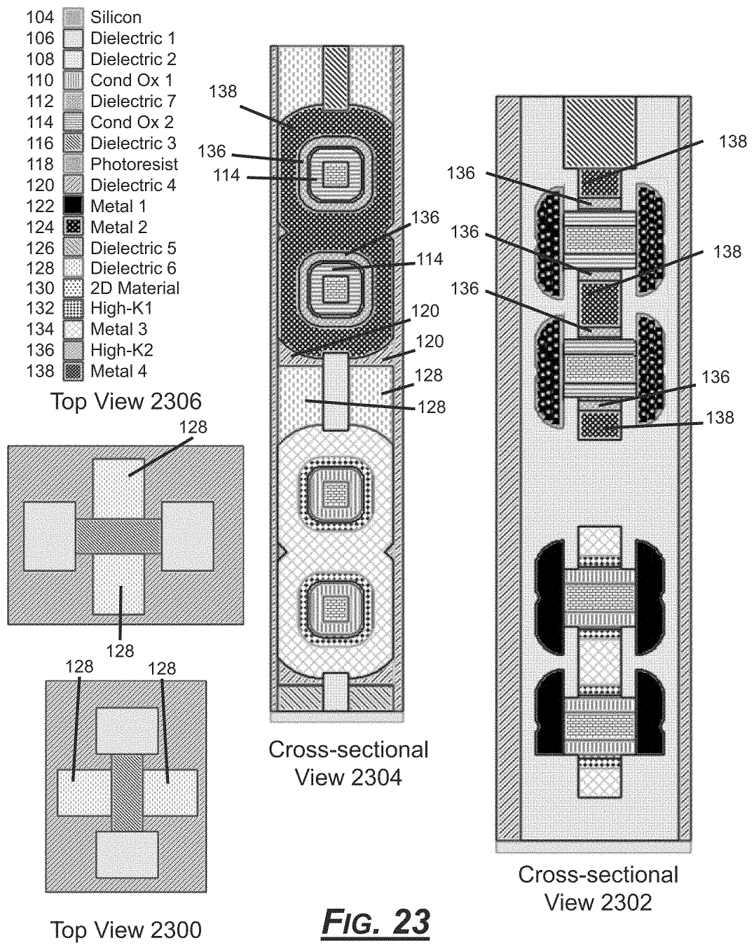

Referring to FIG. 23, illustrated are top views 2300 and 2306 and cross-sectional views 2302 and 2304 of the next stage in the process flow. At this stage in the process flow, the seventh dielectric material 128 can be deposited to fill the remaining gaps in the top of the gate openings, using any suitable material deposition technique. A CMP process may then be performed. Then, the seventh dielectric material 128 can be directionally etched to about halfway through the device, exposing the materials in the stack of layers at the top half of the device in the gate openings. Process steps similar to those described in connection with FIGS. 12-15 can then be performed to form the semiconductive-behaving material 114, the 2D material 130 and to form an active gate (e.g., the high-k dielectric material 136 and the gate metal 138). The seventh dielectric material 128 can then be deposited to fill the remaining gaps in the gate openings at the top of the device, and a CMP process may be performed.

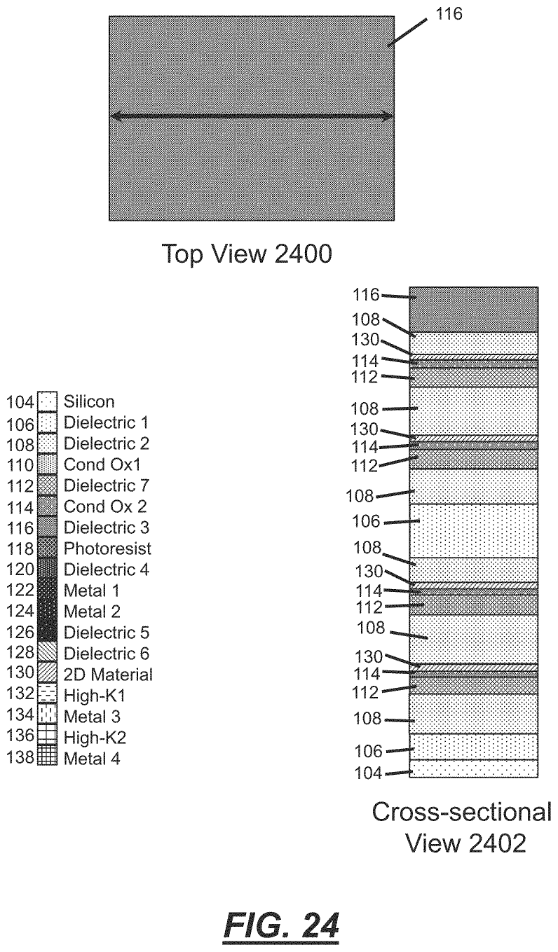

FIGS. 24-26 show various views of a fourth process flow to manufacture semiconductor devices having advanced 3D device architectures using nanosheets with 2D materials, according to an embodiment. FIGS. 24-26 show process steps similar to those described above in connection with FIGS. 1-15, but with an alternative stack of materials, which simplifies certain process steps. Referring to FIG. 24, illustrated is a top view 2400 and a cross-sectional view 2402 of an alternative stack of layers. The alternative stack of layers in FIG. 24 can be similar to that described in connection with FIG. 1, but with only a single layer of the semiconductive-behaving material 114 formed on each layer of the third dielectric material 112. Each layer of the third dielectric material 112 is instead formed on a layer of the second dielectric material 108, as shown. Additionally, the stack of layers includes a layer of the 2D material 130 formed on each layer of the semiconductive-behaving material 114.

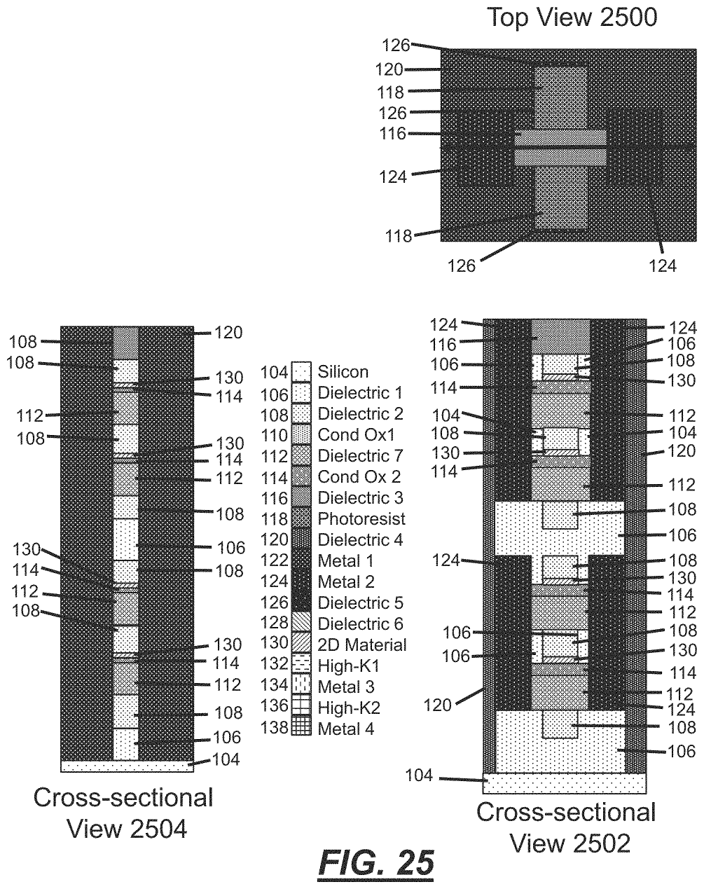

Referring to FIG. 25, illustrated is a top view 2500 and cross-sectional views 2502 and 2504 of the next stage in the process flow. At this stage in the process flow, steps similar to those described in connection with FIGS. 2-9 can be performed on the alternative stack of layers described in connection with FIG. 24. However, in addition to recessing the layers of the second dielectric material 108 via the source/drain openings, as described in connection with FIG. 4, the layer of the 2D material 130 may also be recessed using a similar etching technique. In some implementations, the 2D material 130 may not be etched. If the 2D material 130 is etched, it can later be partially surrounded by the first dielectric material 106 (as shown here), using techniques described in connection with FIG. 5. Then, the metal material 124 can be formed as source/drain contacts in the source/drain openings, as described in connection with FIGS. 6-8, and gate openings can be formed in the alternative stack of materials using the techniques described in connection with FIG. 9.

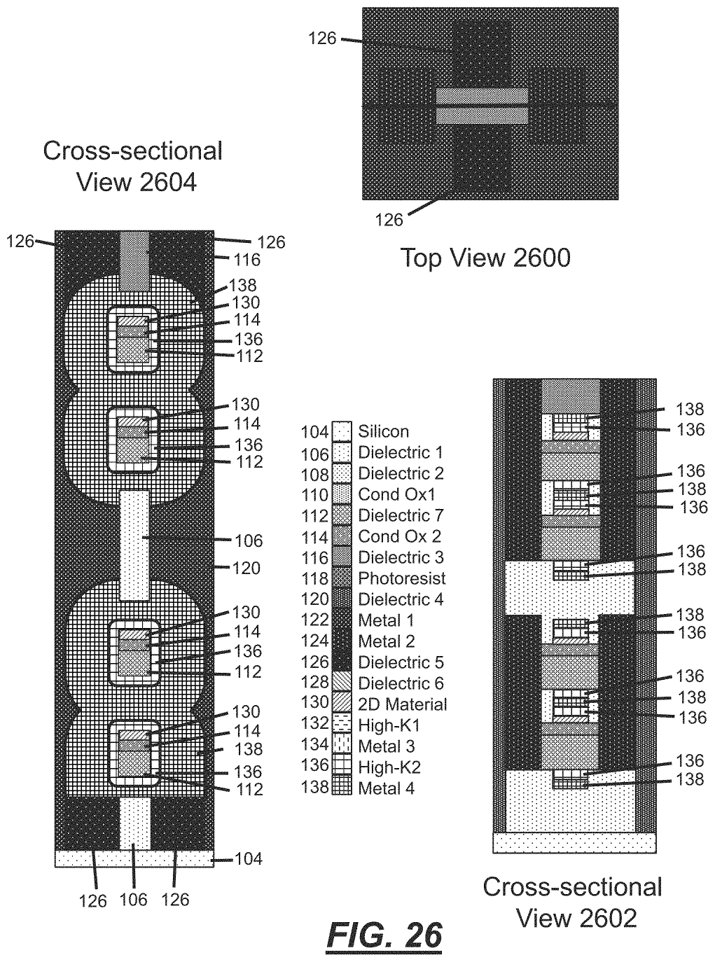

Referring to FIG. 26, illustrated is a top view 2600 and cross-sectional views 2602 and 2604 of the next stage in the process flow. At this stage in the process flow, steps similar to those described in connection with FIGS. 10-11 and 14-15 can be performed. However, rather than etching the semiconductive-behaving material 114 and the second dielectric material 108, as described in connection with FIG. 11, only the second dielectric material 108 is etched via the gate openings, leaving the layers of the third dielectric material 112, the semiconductive-behaving material 114, and the 2D material exposed in the gate openings and intact. Then, the high-k dielectric material 136 and the gate metal 138 can be selectively formed on each stack of the third dielectric material 112, the semiconductive-behaving material 114, and the 2D material 130, using process steps similar to those described in connection with FIGS. 14 and 15. As shown, the high-k dielectric material 136 can be selectively formed around the third dielectric material 112, the semiconductive-behaving material 114, and the 2D material 130 in the gate openings, and the gate metal 138 can be formed around the layers of the high-k dielectric material 136. The sixth dielectric material 126 can be deposited to fill any remaining gaps at the top of the gate openings, and a CMP process may then be performed.

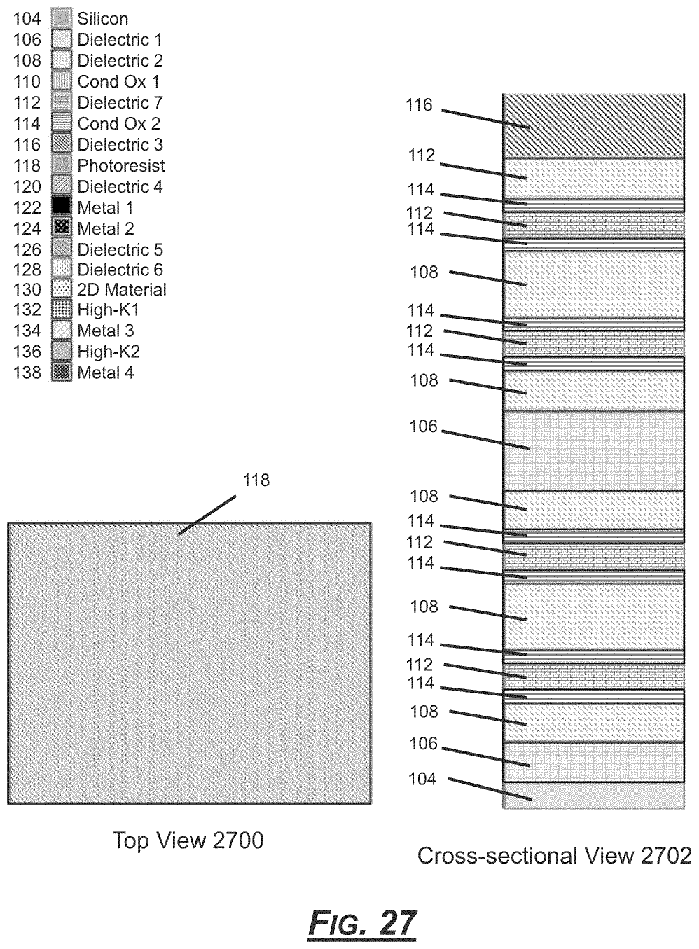

FIGS. 27-34 show various views of a fifth process flow to manufacture semiconductor devices having advanced 3D device architectures using nanosheets with 2D materials, including various alternative process steps, according to an embodiment. Each of the FIGS. 27-34 generally refer to one or more process steps in a process flow, each of which are described in detail in connection with a respective Figure. For the purposes of simplicity and ease of visualization, some reference numbers may be omitted from some Figures. Referring to FIG. 27, illustrated is a top view 2700 and a cross-sectional view 2702 of the stack of layers. The stack of layers in FIG. 27 can be similar to that described in connection with FIG. 1, including layers of the semiconductive-behaving material 114 formed on the top and bottom of layers of the third dielectric material 112.

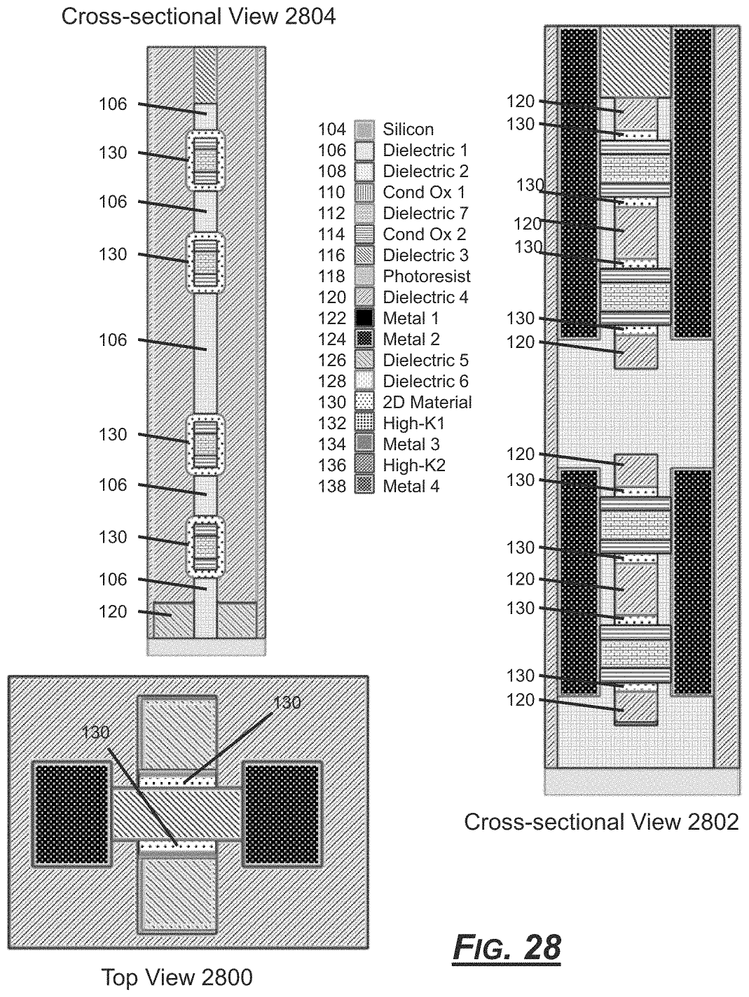

Referring to FIG. 28, illustrated is a top view 2800 and cross-sectional views 2802 and 2804 of the next stage in the process flow. At this stage in the process flow, steps similar to those described in connection with FIGS. 2-11 can be performed. However, rather than removing the layers of the semiconductive-behaving material 114 after directionally etching the sixth dielectric material 126, the semiconductive-behaving material 114 is not etched or otherwise removed. Instead, bridges comprised of layers of the third dielectric material 112 and the semiconductive-behaving material 114 are exposed in the gate openings and in contact with the metal material 124 formed in the source/drain openings. As shown, the 2D material 130 is formed on the layers of the third dielectric material 112 and the semiconductive-behaving material 114 via the gate openings. The 2D material 130 can be formed around the layers of the third dielectric material 112 and the semiconductive-behaving material 114, as shown in the cross-sectional view 2804. The 2D material 130 can be formed using a selective deposition process, or via a material growth process, such that the layers of the third dielectric material 112 and the semiconductive-behaving material 114 behave as seed layers for the 2D material 130.

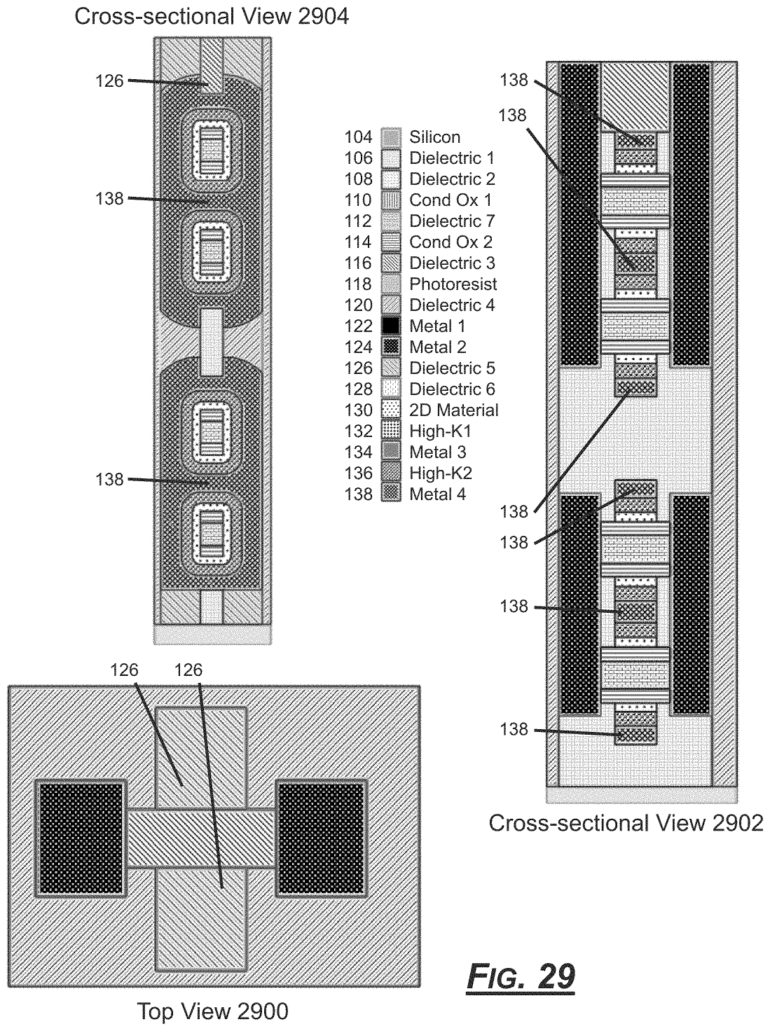

Referring to FIG. 29, illustrated is a top view 2900 and cross-sectional views 2902 and 2904 of the next stage in the process flow. At this stage in the process flow, steps similar to those described in connection with FIGS. 14 and 15 can be performed. As shown, the high-k dielectric material 136 and the gate metal 138 can be selectively formed on the 2D material 130 that surrounds the third dielectric material 112 and the semiconductive-behaving material 114, using process steps similar to those described in connection with FIGS. 14 and 15. As shown, the high-k dielectric material 136 can be selectively formed around the 2D material 130 via the gate openings. The gate metal 138 can then be formed around the layers of the high-k dielectric material 136. The sixth dielectric material 126 can be deposited to fill any remaining gaps at the top of the gate openings, and a CMP process may then be performed.

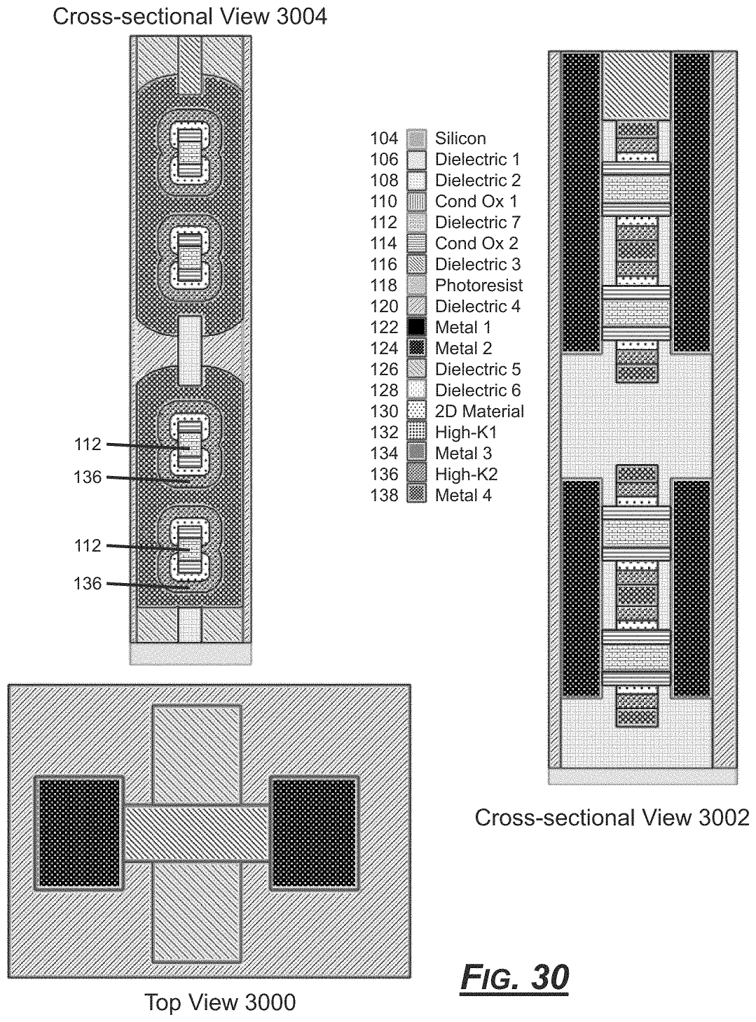

Referring to FIG. 30, illustrated is a top view 3000 and cross-sectional views 3002 and 3004 of the process flow described in connection with FIGS. 28 and 29, but with some alternative process steps. As shown, rather than selectively depositing the 2D material 130 to surround the layers of the third dielectric material 112 and the semiconductive-behaving material 114, the 2D material 130 can be selectively grown on or selectively deposited on the semiconductive-behaving material 114. This results in the geometry of the 2D material 130 shown in the cross-sectional view 3004. Then, the high-k dielectric material 136 can be selectively formed around the 2D material 130 via the gate openings. As shown, the high-k dielectric material 136 can be formed on the 2D material 130 such that it also at least partially contacts the layer of the third dielectric material 112. The gate metal 138 can then be formed around the layers of the high-k dielectric material 136. The sixth dielectric material 126 can be deposited to fill any remaining gaps at the top of the gate openings, and a CMP process may then be performed.

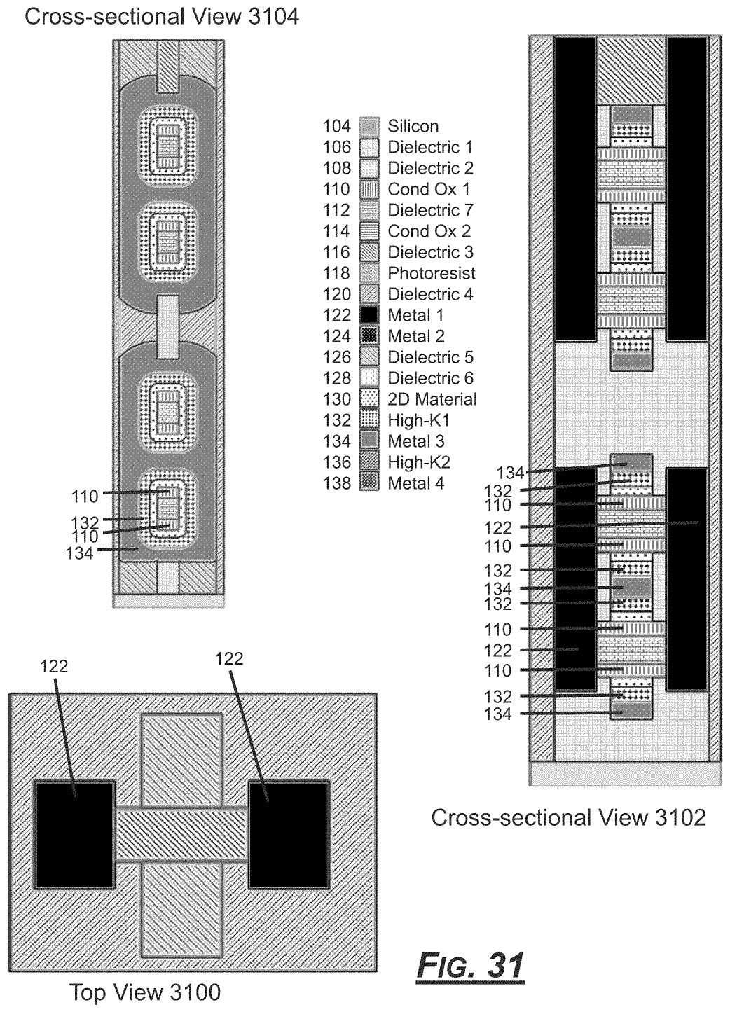

Referring to FIG. 31, illustrated is a top view 3100 and cross-sectional views 3102 and 3104 of the process flow described in connection with FIGS. 28 and 29, but formed using the alternative materials described in connection with FIGS. 16-18. Rather than using the semiconductive-behaving material 114, the second semiconductive-behaving material 110 can be used. Likewise, the second metal material 122 can be formed as the source/drain contacts in the source/drain openings, the second high-k dielectric material 132 can be utilized instead of the high-k dielectric material 136, and the second gate metal 134 can be used instead of the gate metal 138. The alternative materials may be selected based on a desired polarity of the transistor structures. For example, the materials selected for the process flow described in connection with FIGS. 28 and 29 may create N-type transistor devices, while the alternative materials selected for the process flow of FIG. 31 may create P-type transistor devices.

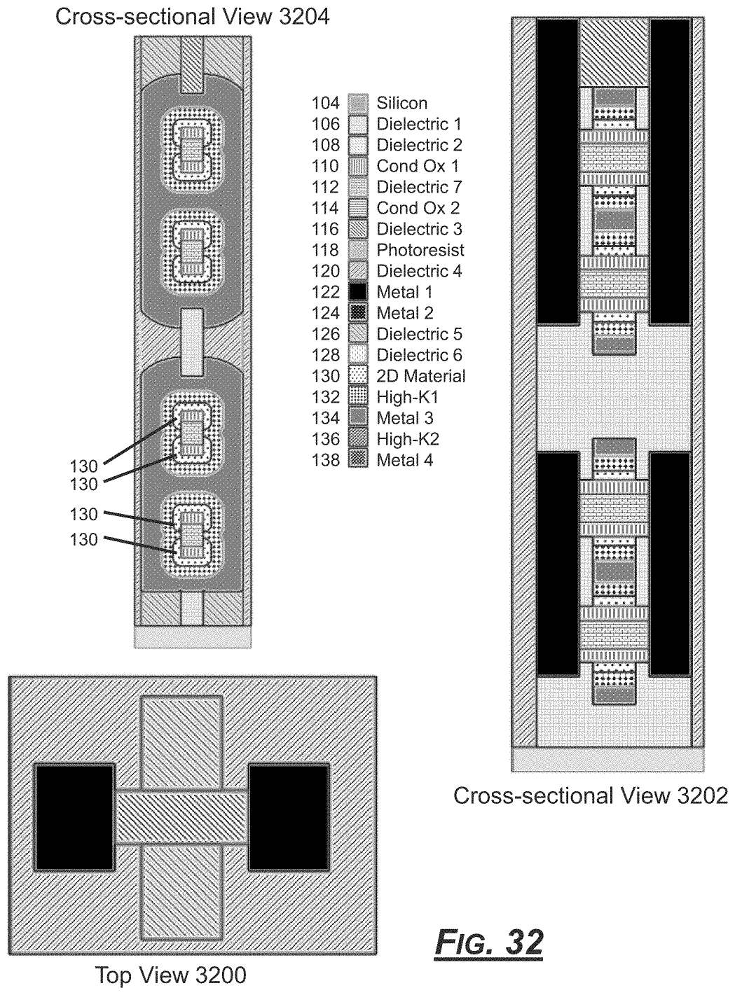

Referring to FIG. 32, illustrated is a top view 3200 and cross-sectional views 3202 and 3204 of the process flow described in connection with FIG. 30, but formed using the alternative materials described in connection with FIGS. 16-18. Much like the process flow described in connection with FIG. 31, rather than using the semiconductive-behaving material 114, the second semiconductive-behaving material 110 can be used. Likewise, the second metal material 122 can be formed as the source/drain contacts in the source/drain openings, the second high-k dielectric material 132 can be utilized instead of the high-k dielectric material 136, and the second gate metal 134 can be used instead of the gate metal 138.

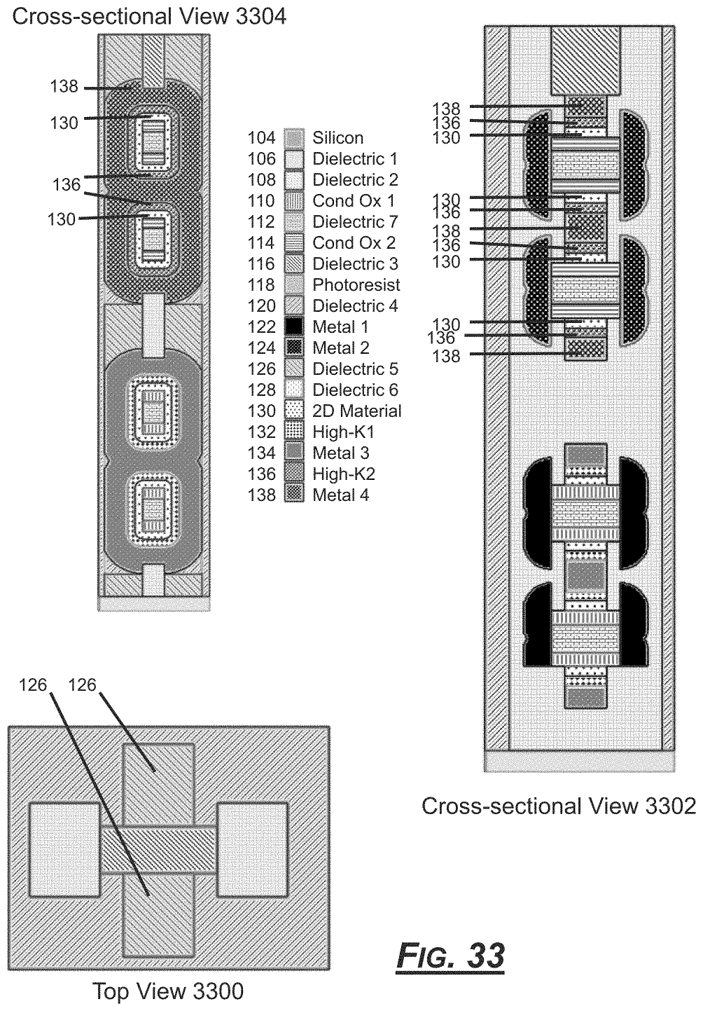

Referring to FIG. 33, illustrated is a top view 3300 and cross-sectional views 3202 and 3204 of a process flow similar to that described in connection with FIGS. 28 and 29, but forming devices with complementary using some of the process steps described in connection with FIGS. 19-23. To form the device shown, process steps similar to those described in connection with FIGS. 19-21 can be performed. However, rather than etching and reforming the second semiconductive-behaving material 110 as described in connection with FIG. 22, only the second dielectric material 108 can be removed, leaving the second semiconductive-behaving material 110 intact and exposed in the gate openings. Then, a layer of the 2D material 130 can be selectively formed around the layers of the third dielectric material 112 and the second semiconductive-behaving material 110, using techniques similar to those described in connection with FIG. 28. Layers of the second high-k dielectric material 132 and the gate metal 134 can be formed to create an active gate on the 2D material 130 that surrounds the layers of the third dielectric material 112 and the second semiconductive-behaving material 110. Similar processes can be repeated on the upper layers of the third dielectric material 112 and the semiconductive-behaving material 114, to form the 2D material 130, the high-k dielectric material 136, and the gate metal 138, on the upper layers of the third dielectric material 112 and the semiconductive-behaving material 114.

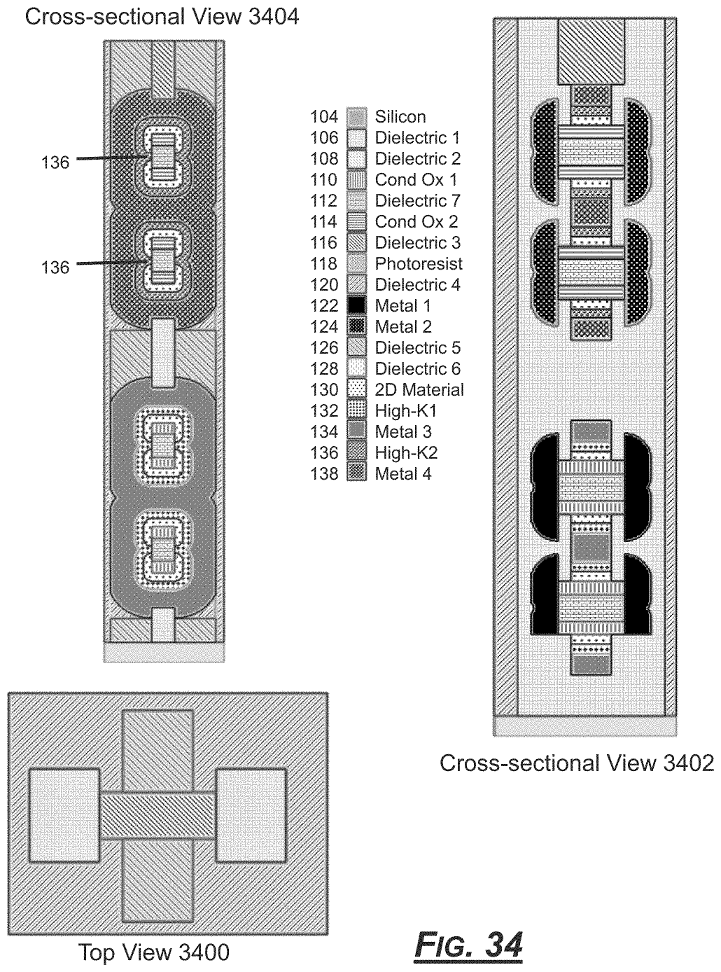

Referring to FIG. 34, illustrated is a top view 3400 and cross-sectional views 3402 and 3404 of the process flow described in connection with FIG. 33, with the alternative 2D material 130 formation steps described in connection with FIG. 30. Rather than selectively depositing the 2D material 130 around the upper layers of the third dielectric material 112 and the semiconductive-behaving material 114 and the lower layers of the third dielectric material 112 and the second semiconductive-behaving material 110, the 2D material 130 can be selectively grown or selectively deposited on the semiconductive-behaving material 114 and the second semiconductive-behaving material 110. This results in the geometry of the 2D material 130 shown in the cross-sectional view 3404, which alters the geometry of the high-k dielectric material 136, the second high-k dielectric material 136, the gate metal 138, and the second gate metal 134.

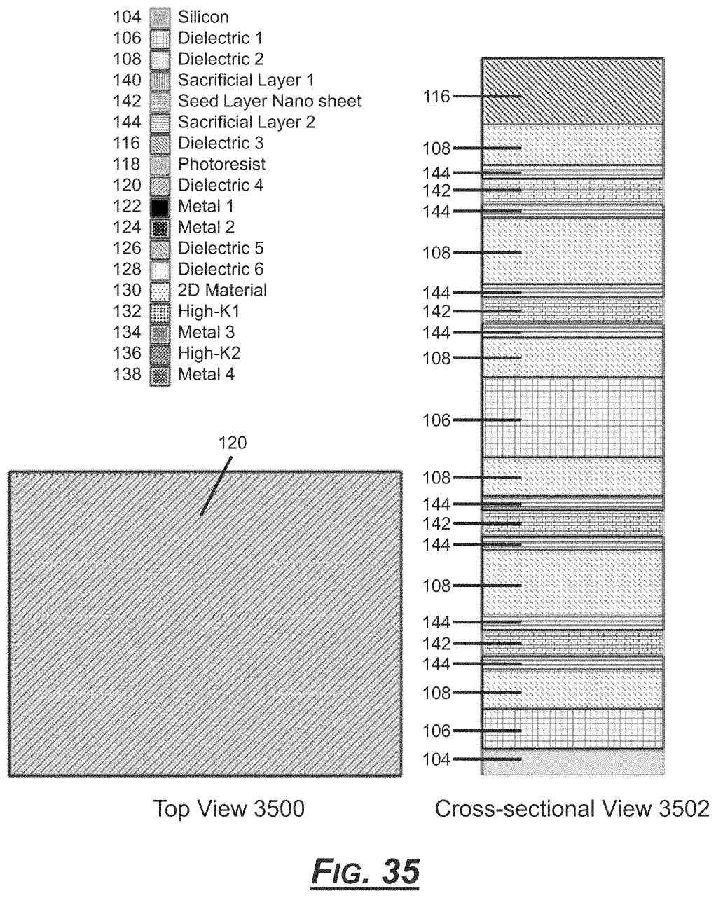

FIGS. 35-40 show various views of a sixth process flow to manufacture semiconductor devices having advanced 3D device architectures using nanosheets with 2D materials, according to an embodiment. Each of the FIGS. 35-40 generally refer to one or more process steps in a process flow, each of which are described in detail in connection with a respective Figure. For the purposes of simplicity and ease of visualization, some reference numbers may be omitted from some Figures. FIGS. 35-40 show process steps similar to those described above in connection with FIGS. 1-15, but utilizing seed layer nanosheet materials and sacrificial material layers instead of the layers of the semiconductive-behaving material 114 and the third dielectric material 112. Referring to FIG. 35, illustrated is a top view 3500 and a cross-sectional view 3502 of the stack of layers including these alternative layers. The stack of layers in FIG. 35 is similar to the stack of layers described in connection with FIG. 1, but with layers of a seed material 142 (shown in the legend as the “Seed Layer Nanosheet”) formed in the stack in place of the third dielectric material 112 shown in FIG. 1, and with layers of a sacrificial material 144 (shown in the legend as the “Sacrificial Layer 2”) formed in the stack in place of the semiconductive-behaving material 114 shown in FIG. 1. The sacrificial material 144 may be chosen, for example, based on a desired polarity of the transistor structures formed in this process flow. Any suitable sacrificial material 144 may be chosen that can be selectively removed from the stack of layers in further process steps. For example, the sacrificial material 144 may be a dielectric material, a metal material, or another type of material that can be selectively etched or removed from the stack of layers.

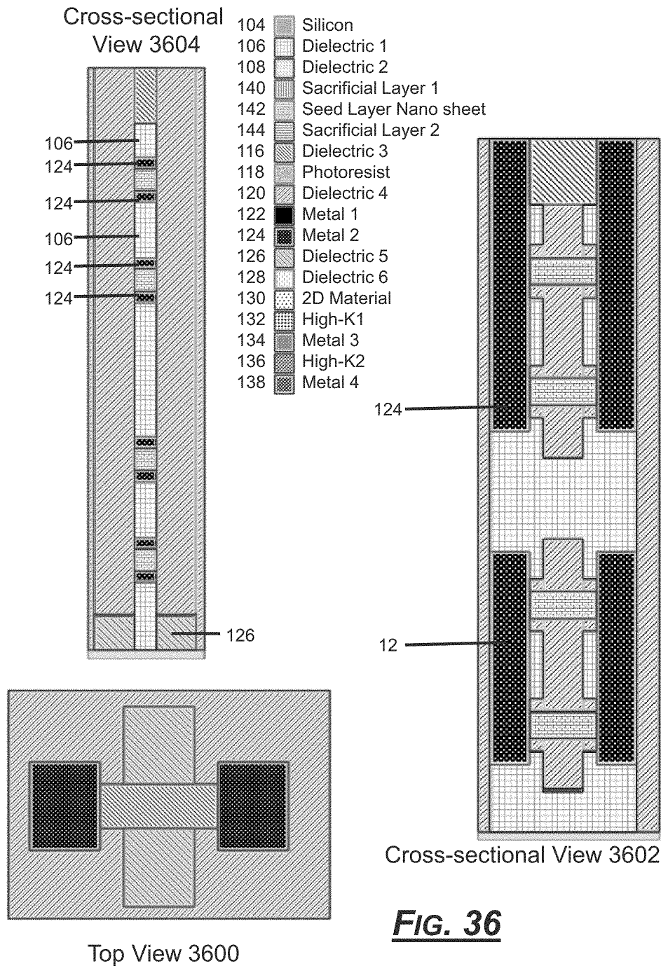

Referring to FIG. 36, illustrated is a top view 3600 and cross-sectional views 3602 and 3604 of the next stage in the process flow. At this stage in the process flow, steps similar to those described in connection with FIGS. 2-11 can be performed. As shown, the source/drain metal 124 has been formed in source/drain openings in the fifth dielectric material 120 of the stack of layers. Additionally, the second dielectric material 108 has been recessed and then ultimately removed via the gate openings in the stack of layers. Rather than removing the layers of the semiconductive-behaving material 114 and leaving the layers of the third dielectric material 112 extending between the source/drain contacts, the sacrificial material 144 has been removed, exposing the layers of the seed material 142 in the gate openings. The seed material 142 may be used as a base material to grow the 2D material 130 in later process steps.

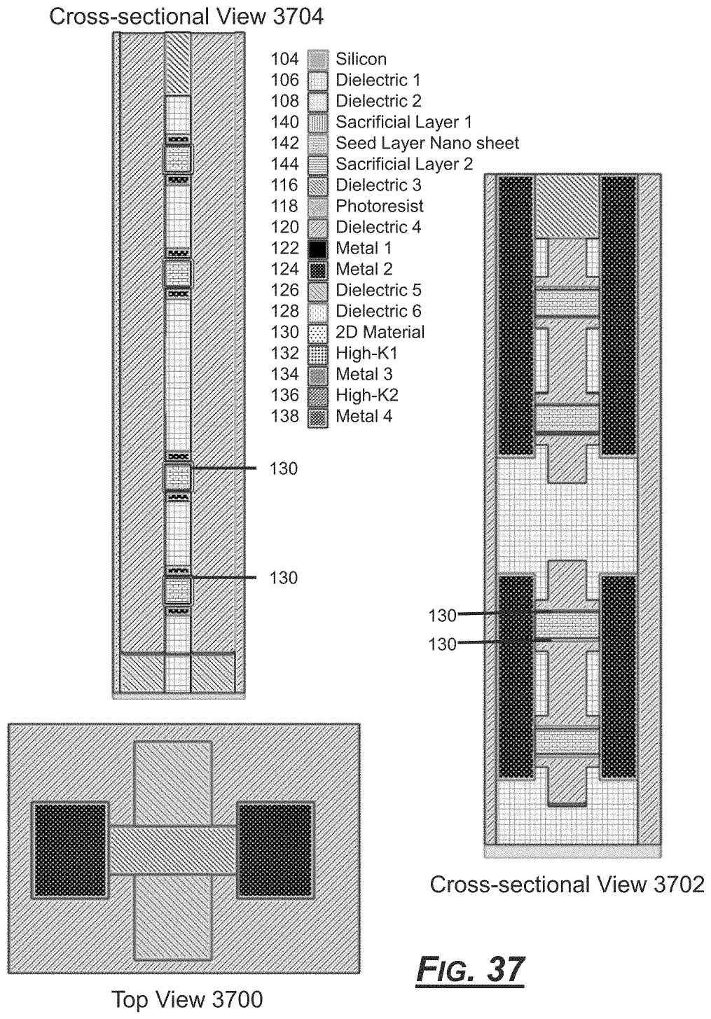

Referring to FIG. 37, illustrated is a top view 3700 and cross-sectional views 3702 and 3704 of the next stage in the process flow. At this stage in the process flow, the 2D material 130 can be selectively formed on the exposed layers of the seed material 142 via the gate openings. The 2D material 130 can be formed around the layers of the seed material 142. The 2D material 130 can be selectively deposited on the seed material 142, for example, using any suitable material deposition technique, including ALD, CVD, PVD, PECVD, or epitaxial techniques, among others. In some implementations, the 2D material 130 can be selectively grown on the seed material 142, such that the seed material 142 behaves as a seed for the 2D material 130.

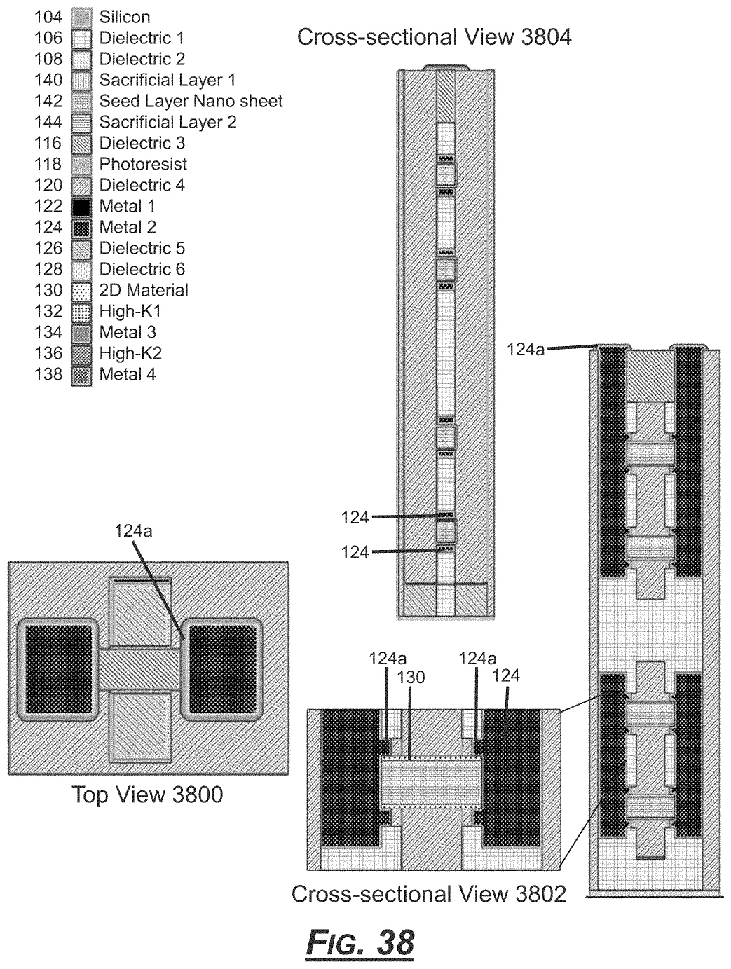

Referring to FIG. 38, illustrated is a top view 3800 and cross-sectional views 3802 and 3804 of the next stage in the process flow. At this stage in the process flow, additional metal material 124a can be added to each of the source/drain contacts (formed from the metal material 124 in previous process steps) to selectively expand the source/drain contacts. The additional metal material 124a can be selectively grown on the source/drain contacts. Any suitable material formation technique can be used to form the metal material 124a on the source/drain contacts, including ALD, CVD, PVD, PECVD, or epitaxial techniques, among others. In some implementations, the additional metal material 124a can be selectively grown on the source/drain contacts such that the source/drain contacts (e.g., the metal material 124 previously deposited in the source/drain openings) behave as a seed material for the metal material 124a. Forming additional metal material 124a provides a greater contact surface area between the source/drain contacts and the 2D material 130. The metal material 124a can be selectively formed on the existing source/drain contacts until a predetermined contact surface area between the source/drain contacts and the 2D material 130 has been achieved.

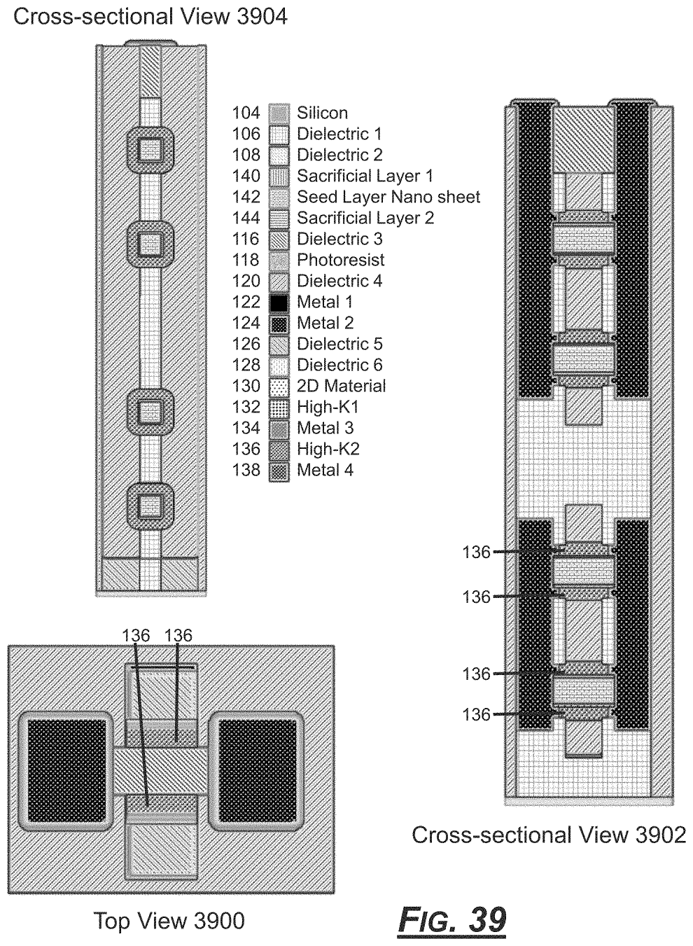

Referring to FIG. 39, illustrated is a top view 3900 and cross-sectional views 3902 and 3904 of the next stage in the process flow. At this stage in the process flow, the high-k dielectric material 136 can be selectively formed on the 2D material 130. To do so, process steps similar to those described in connection with FIG. 14 can be performed. The high-k dielectric material 136 acts as a gate dielectric material for the channel formed from the 2D material 130. The high-k dielectric material 136 can be any type of material with a relatively high dielectric constant and may be deposited at a predetermined thickness to achieve a desired capacitance. In some implementations, the high-k dielectric material 136 can be selectively deposited or grown, such that the high-k dielectric is deposited only on the 2D material 130. The high-k dielectric material 136 may be deposited using any suitable material deposition technique, including but not limited to ALD, CVD, PVD, or PECVD, among others.

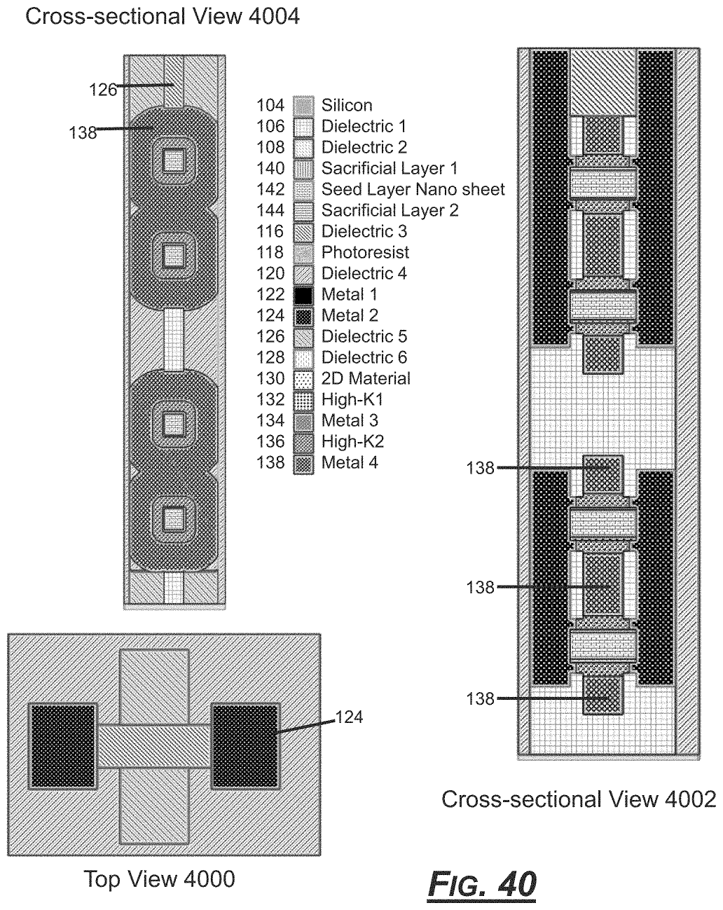

Referring to FIG. 40, illustrated is a top view 4000 and cross-sectional views 4002 and 4004 of the next stage in the process flow. At this stage in the process flow, the gate metal 138 can be selectively formed on the high-k dielectric material 136 via the gate openings. To do so, process steps similar to those described in connection with FIG. 15 can be performed. The gate metal 138 may be deposited using any suitable material deposition technique, including but not limited to ALD, CVD, PVD, or PECVD, among others. In some implementations, the gate metal 138 may be grown on the high-k dielectric material 136, such that the high-k dielectric material 136 behaves as a seed material for the gate metal 138. Although the gate metal 138 is shown here as completely surrounding both bottom transistor structures, it should be understood that dielectric layers, etching, or other techniques may be used to isolate the gate metal 138 for each transistor from one another. Once the gate metal 138 is selectively deposited on the high-k dielectric material 136, the sixth dielectric material 126 can be deposited to fill the remaining space at the top of the gap openings. After depositing the sixth dielectric material 126, a CMP process can be performed.

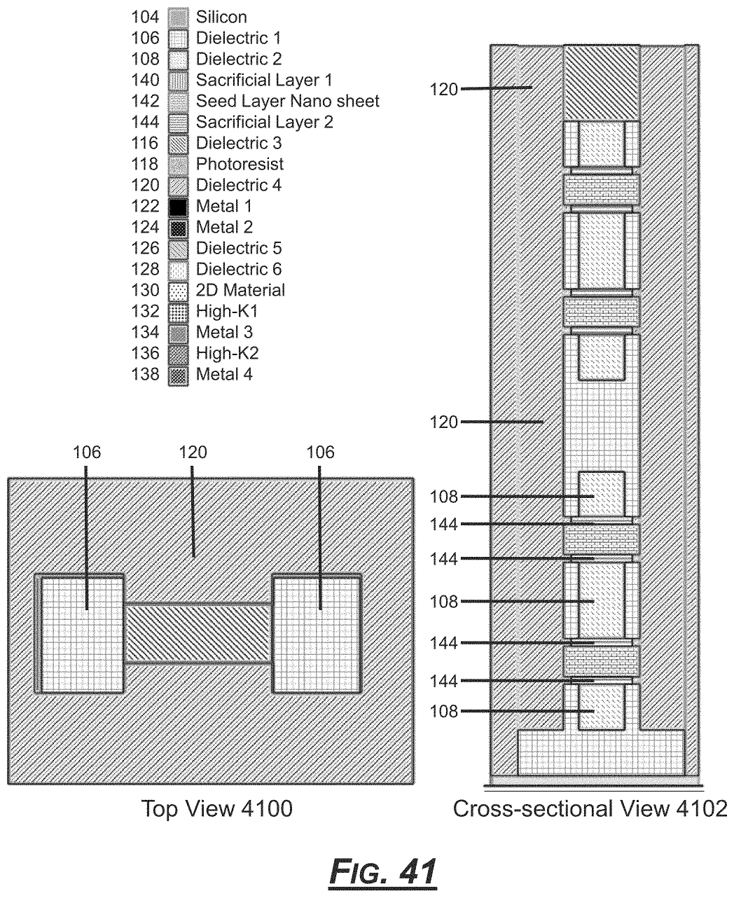

FIGS. 41-46 show various views of a seventh process flow to manufacture semiconductor devices having advanced 3D device architectures using nanosheets with 2D materials, according to an embodiment. Each of the FIGS. 41-46 generally refer to one or more process steps in a process flow, each of which are described in detail in connection with a respective Figure. For the purposes of simplicity and ease of visualization, some reference numbers may be omitted from some Figures. FIGS. 41-46 show process steps similar to those described above in connection with FIGS. 35-40, but using alternative process steps to increase the contact surface area between the metal material 124 and the 2D material 130. Referring to FIG. 41, illustrated is a top view 4100 and a cross-sectional view 4102 of a stack of layers similar to the stack of layers described in connection with FIG. 35, after being subjected to process steps similar to those described in connection with FIGS. 2-5. Additionally, after directionally etching the first dielectric material 106, the layers of the sacrificial material 144 can be partially recessed partially via the source/drain openings, as shown in the cross-sectional view 4102. Any suitable etching or material removal technique can be used to recess the layers of the sacrificial material 144, including but not limited to dry etching, wet etching, or plasma etching techniques, among others.

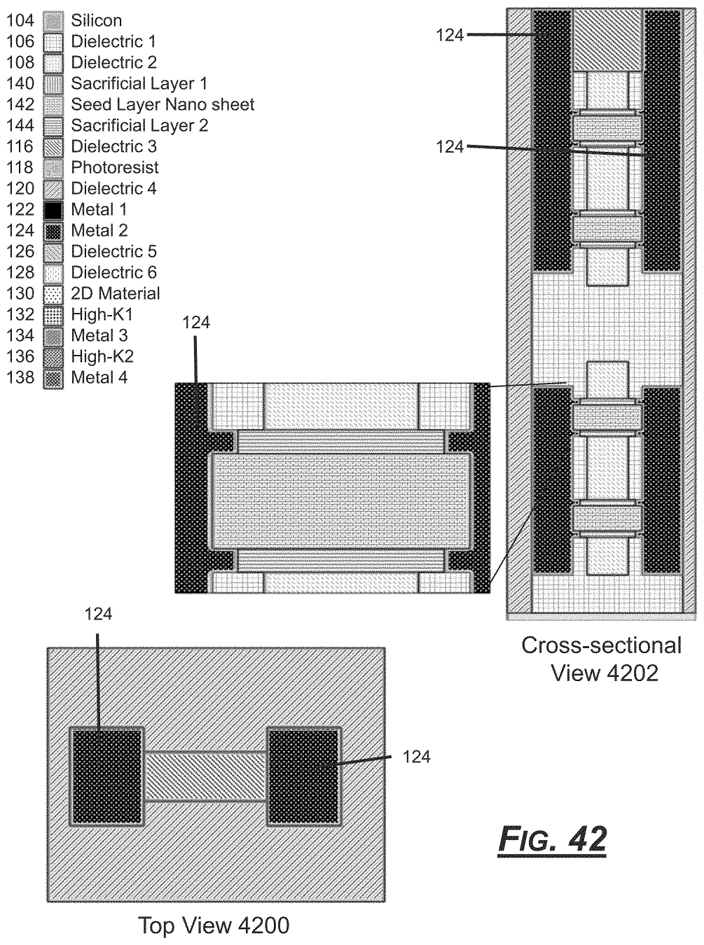

Referring to FIG. 42, illustrated is a top view 4200 and a cross-sectional view 4202 of the next stage in the process flow. At this stage in the process flow, source/drain contacts can be formed from the metal material 124 for the upper and lower transistor structures using the process steps described in connection with FIGS. 6-8. As shown in the cross-sectional view 4202, the metal material 124 fills the gaps left when recessing the layers of the sacrificial material 144 in the previous process step. This increased metal area will later increase the contact surface area between the source/drain contacts and the 2D material 130.

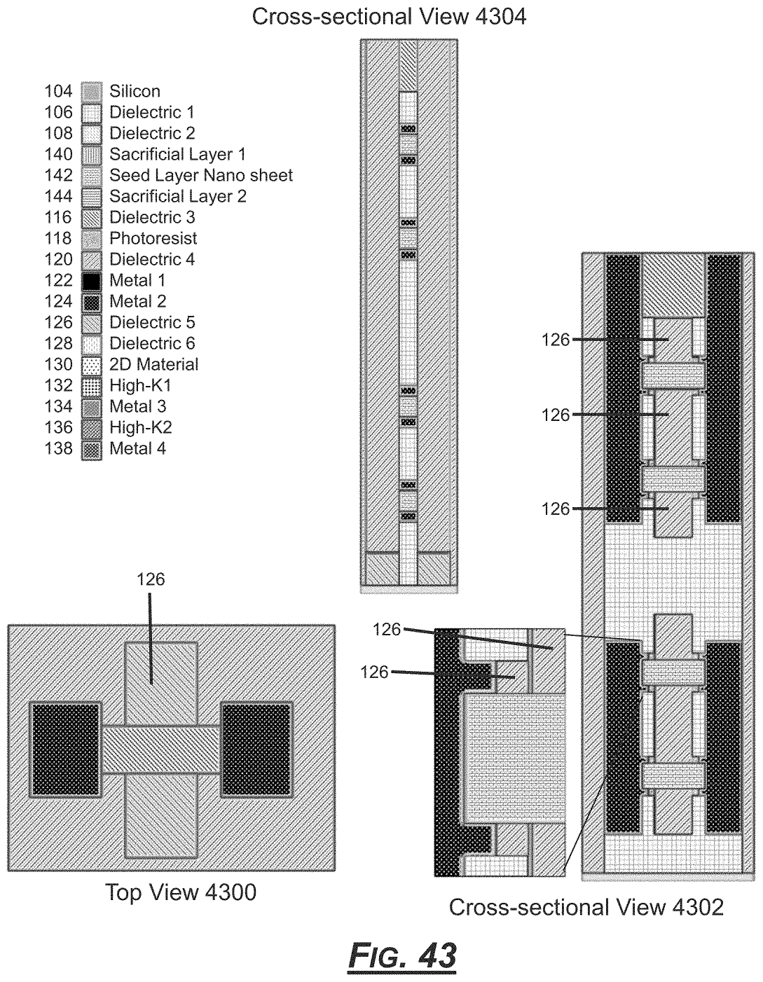

Referring to FIG. 43, illustrated is a top view 4300 and cross-sectional views 4302 and 4304 of the next stage in the process flow. At this stage in the process flow, steps similar to those described in connection with FIGS. 9-11 can be performed. However, rather than removing the layers of the semiconductive-behaving material 114 and leaving the layers of the third dielectric material 112 extending between the source/drain contacts as in FIG. 11, the sacrificial material 144 has been removed, exposing the layers of the seed material 142 in the gate openings. The seed material 142 may be used as a base material to grow the 2D material 130 in later process steps.

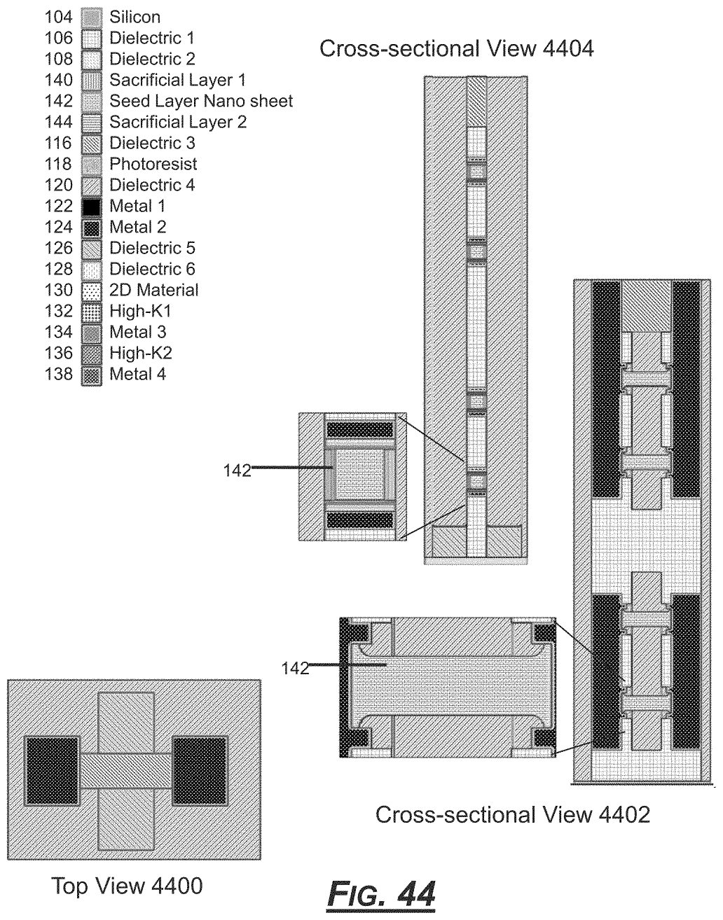

Referring to FIG. 44, illustrated is a top view 4400 and cross-sectional views 4402 and 4404 of the next stage in the process flow. At this stage in the process flow, the layers of the seed material 142 can be partially recessed via the gate openings. To recess the layers of the seed material 142, a selective etching or material removal process may be performed. Any suitable etching or material removal technique can be used to recess the layers of the seed material 142, including but not limited to dry etching, wet etching, or plasma etching techniques, among others. Recessing the layers of the seed material 142 can create a gap between the seed material 142 and the metal material 124. This gap can be filled with the 2D material 130 in later process steps and serves to increase the contact surface area between the metal material 124 and the 2D material 130.

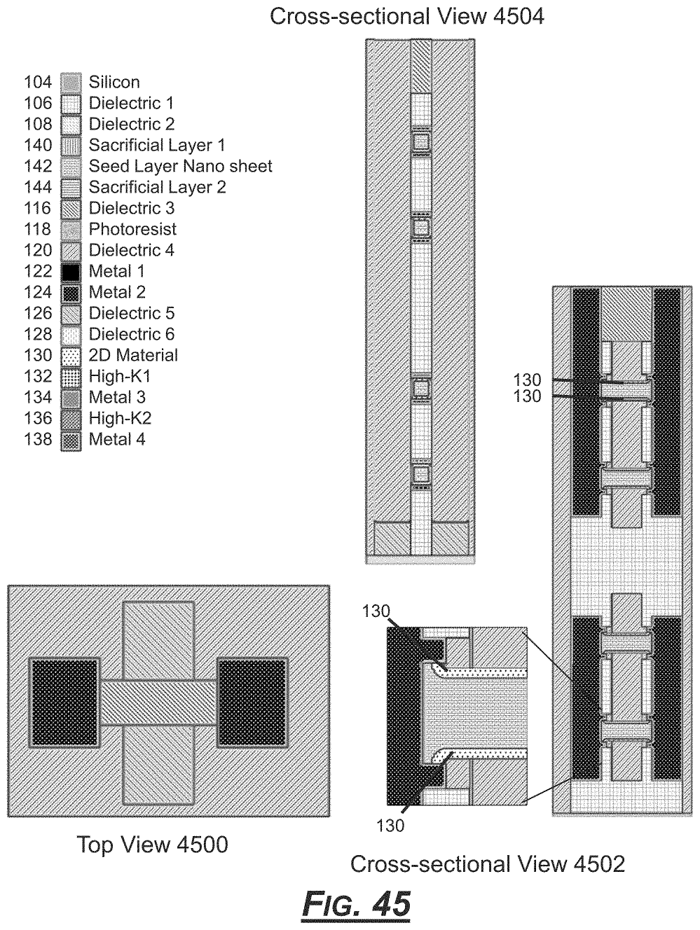

Referring to FIG. 45, illustrated is a top view 4500 and cross-sectional views 4502 and 4504 of the next stage in the process flow. At this stage in the process flow, the 2D material 130 can be selectively formed on the exposed layers of the seed material 142 via the gate openings. The 2D material 130 can be formed around the layers of the seed material 142. The 2D material 130 can be selectively deposited on the seed material 142, for example, using any suitable material deposition technique, including ALD, CVD, PVD, PECVD, or epitaxial techniques, among others. In some implementations, the 2D material 130 can be selectively grown on the seed material 142, such that the seed material 142 behaves as a seed for the 2D material 130. As shown, the 2D material 130 is formed to fill the gaps between the recessed seed material 142 and the metal material 124.

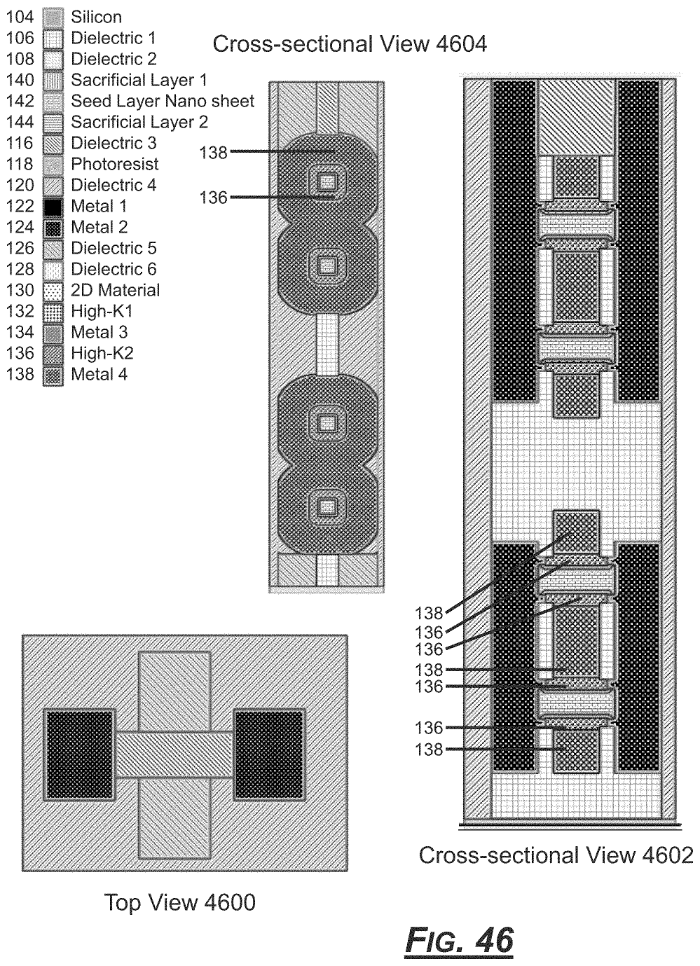

Referring to FIG. 46, illustrated is a top view 4600 and cross-sectional views 4602 and 4604 of the next stage in the process flow. At this stage in the process flow, the high-k dielectric material 136 and the gate metal 138 can be formed on the 2D material, using process steps similar to those described in connection with FIGS. 39 and 40. The high-k dielectric material 136 may be selectively formed on the 2D material 130 using any suitable material deposition technique, including but not limited to ALD, CVD, PVD, or PECVD, among others. The gate metal 138 may be selectively formed on the high-k dielectric material 136 using any suitable material deposition technique, including but not limited to ALD, CVD, PVD, or PECVD, among others. In some implementations, the gate metal 138 may be grown on the high-k dielectric material 136, such that the high-k dielectric material 136 behaves as a seed material for the gate metal 138. Although the gate metal 138 is shown here as completely surrounding both bottom transistor structures, it should be understood that dielectric layers, etching, or other techniques may be used to isolate the gate metal 138 for each transistor from one another. Once the gate metal 138 is selectively deposited on the high-k dielectric material 136, the sixth dielectric material 126 can be deposited to fill the remaining space at the top of the gap openings. After depositing the sixth dielectric material 126, a CMP process can be performed.

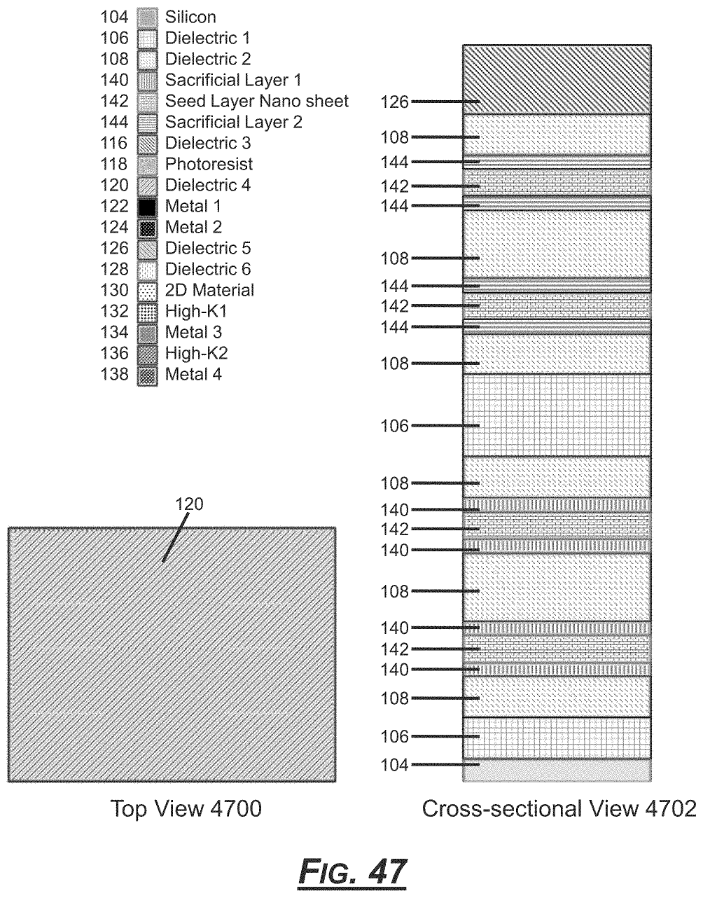

FIGS. 47-55 show various views of an eighth process flow to manufacture semiconductor devices having advanced 3D device architectures using nanosheets with 2D materials, according to an embodiment. Each of the FIGS. 47-55 generally refer to one or more process steps in a process flow, each of which are described in detail in connection with a respective Figure. For the purposes of simplicity and ease of visualization, some reference numbers may be omitted from some Figures. FIGS. 47-55 show process steps similar to those described above in connection with FIGS. 35-40, but forming devices having complementary polarity, such as those formed using the process steps described in connection with FIGS. 19-23.

Referring to FIG. 47, illustrated is a top view 4700 and a cross-sectional view 4702 of the stack of layers including these alternative layers. The stack of layers in FIG. 47 is similar to the stack of layers described in connection with FIG. 19, but with layers of the seed material 142 formed in the stack in place of the third dielectric material 112 shown in FIG. 19, with layers of the sacrificial material 144 formed in the stack in place of the semiconductive-behaving material 114 shown in FIG. 19 and with layers of a second sacrificial material 140 (shown in the legend as the “Sacrificial Layer 1”) formed in the stack in place of the second semiconductive-behaving material 110. The sacrificial material 144 and the second sacrificial material 140 may be chosen, for example, based on a desired polarity of the transistor structures formed in this process flow. Any suitable materials may be chosen for the sacrificial material 144 and the second sacrificial material 140 that can be selectively removed from the stack of layers in further process steps. For example, the sacrificial material 144 and the second sacrificial material 140 may be a dielectric material, a metal material, or another type of material that can be selectively etched or removed from the stack of layers.

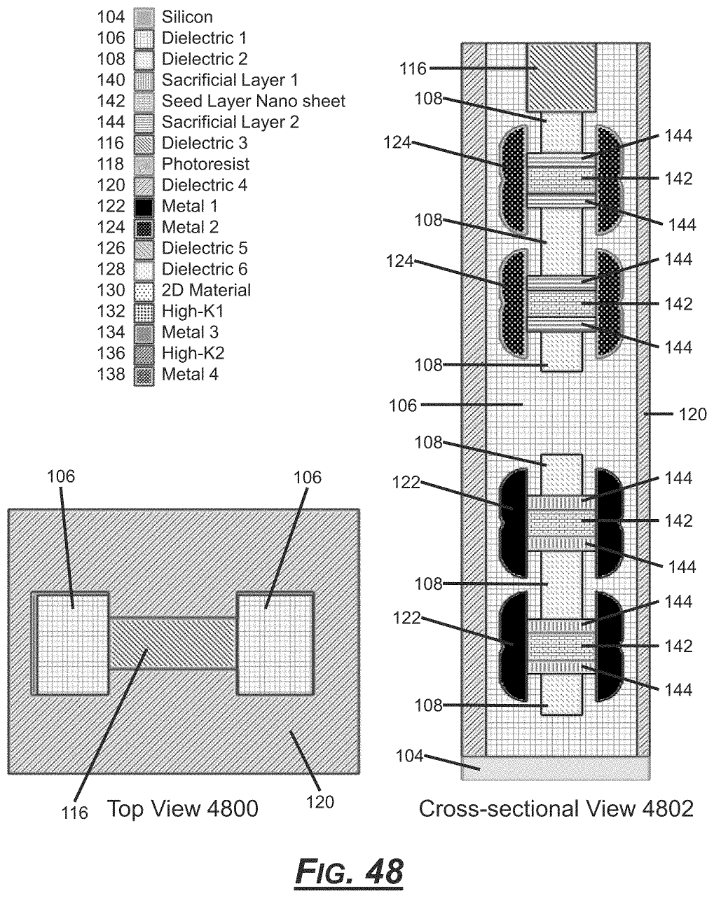

Referring to FIG. 48, illustrated is a top view 4800 and a cross-sectional view 4802 of the next stage in the process flow. At this stage in the process flow, process steps similar to those described in connection with FIG. 20 can be performed. However, rather than selectively forming the metal material 124 on the semiconductive-behaving material 114 and selectively forming the second metal material 122 on the second semiconductive-behaving material 110, the metal material 124 can be selectively formed on the layers of the sacrificial material 144 in the source/drain openings, and the second metal material 122 can be selectively formed on the layers of the second sacrificial material 140. Then, like the process steps described in connection with FIG. 20, the first dielectric material 106 can be deposited to fill any remaining gaps in the source/drain openings, and a CMP process may be performed.

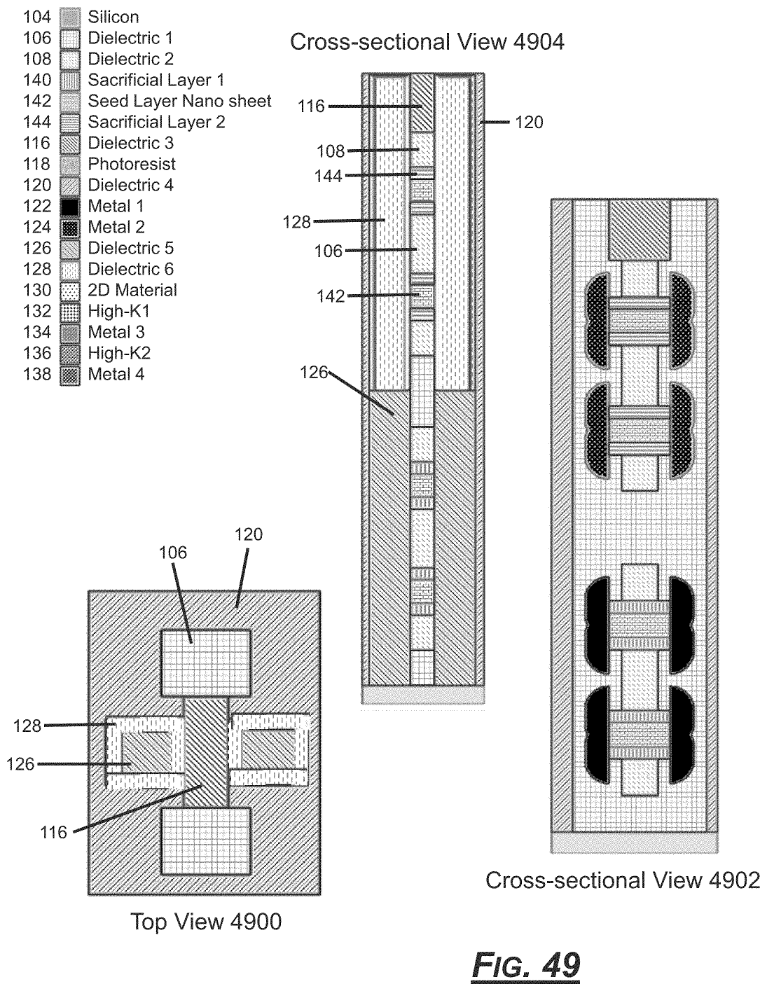

Referring to FIG. 49, illustrated is a top view 4900 and cross-sectional views 4902 and 4904 of the next stage in the process flow. At this stage in the process flow, process steps similar to those described in connection with FIG. 21 can be performed. As shown, the sixth dielectric material can be deposited in the gate openings and then etched halfway down the stack of layers, such that the top two transistor structures are exposed in the gate openings. Then, a thin layer of the seventh dielectric material 128 can be formed in the gate layers using any suitable material deposition technique, including ALD, CVD, PVD, PECVD, or epitaxial techniques, among others. The seventh dielectric material 128 can then be directionally etched to expose the sixth dielectric material 126 in the gate openings.

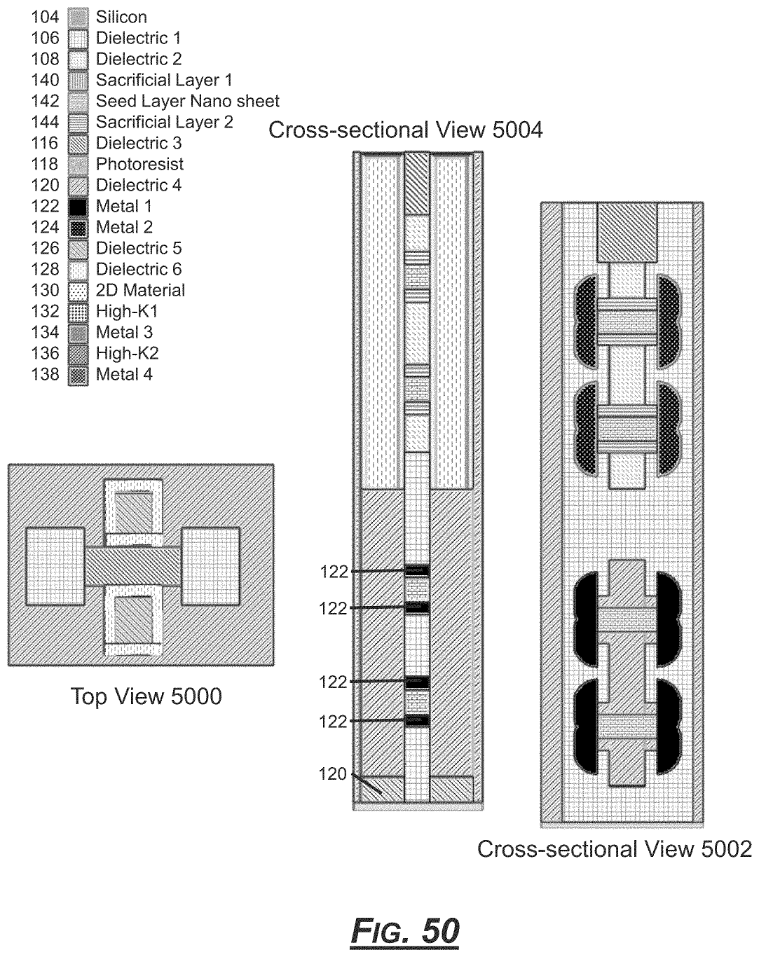

Referring to FIG. 50, illustrated is a top view 5000 and cross-sectional views 5002 and 5004 of the next stage in the process flow. At this stage in the process flow, some process steps similar to those described in connection with FIG. 22 can be performed. In particular, the sixth dielectric material 126 can be directionally etched to expose the layers of the second sacrificial material 140 and the seed material 142 in the gate openings. Some of the sixth dielectric material 126 can remain in the bottom of the gate openings, isolating the exposed layers from the base layer 104. Then, the second dielectric material 108 and the second sacrificial material 140 can be selectively removed from the stack of layers via the gate openings. Any suitable etching or material removal technique can be used, including but not limited to dry etching, wet etching, or plasma etching techniques, among others. The seventh dielectric material 128 protects the layers in the upper half of the device from the etching process, as shown.

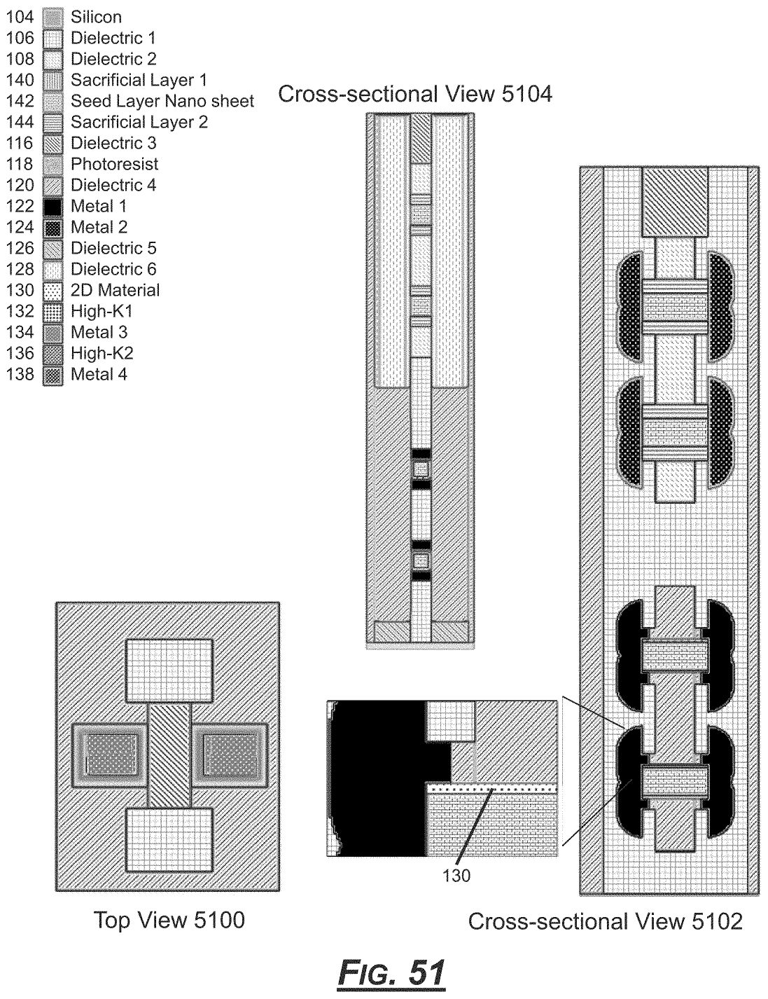

Referring to FIG. 51, illustrated is a top view 5100 and cross-sectional views 5102 and 5104 of the next stage in the process flow. At this stage in the process flow, process steps similar to those described in connection with FIGS. 37 and 38 can be performed, except that the second metal material 122 is selectively formed on the source/drain contacts in the lower half of the device, rather than the metal material 124. To do so, first the 2D material 130 can be formed around the layers of the seed material 142. The 2D material 130 can be selectively deposited on the seed material 142, for example, using any suitable material deposition technique, including ALD, CVD, PVD, PECVD, or epitaxial techniques, among others. In some implementations, the 2D material 130 can be selectively grown on the seed material 142, such that the seed material 142 behaves as a seed for the 2D material 130. Then, each of the source/drain contacts in the bottom half of the device (shown here as formed from the second metal material 122) can be selectively expanded, by selectively growing the second metal material 122 on the source/drain contacts. Any suitable material formation technique can be used to form the second metal material 122 on the source/drain contacts, including ALD, CVD, PVD, PECVD, or epitaxial techniques, among others. In some implementations, the second metal material 122 can be selectively grown on the source/drain contacts, such that the source/drain contacts (e.g., the second metal material 122 previously formed in the source/drain openings) behave as a seed material for the second metal material 122. Forming additional portions of the second metal material 122 provides a greater contact surface area between the second metal material 122 and the 2D material 130. The second metal material 122 can be selectively formed on the existing source/drain contacts until a predetermined contact surface area between the second metal material 122 and the 2D material 130 has been achieved.

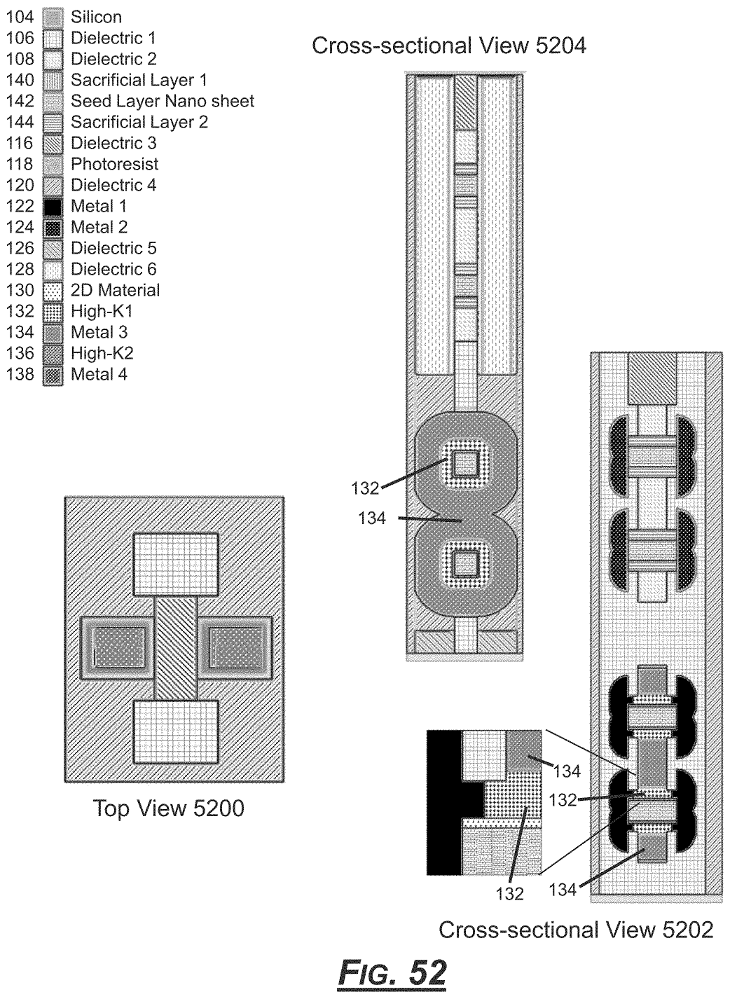

Referring to FIG. 52, illustrated is a top view 5200 and cross-sectional views 5202 and 5204 of the next stage in the process flow. At this stage in the process flow, the remaining process described in connection with FIG. 22 can be performed to form the second high-k dielectric material 132 and the second gate metal 134 in the bottom half of the stack of layers. As shown, the seventh dielectric material 128 can protect the layers of material exposed in the gate openings at the top half of the device from the selective deposition techniques used to form the transistor structures at the bottom half of the device.

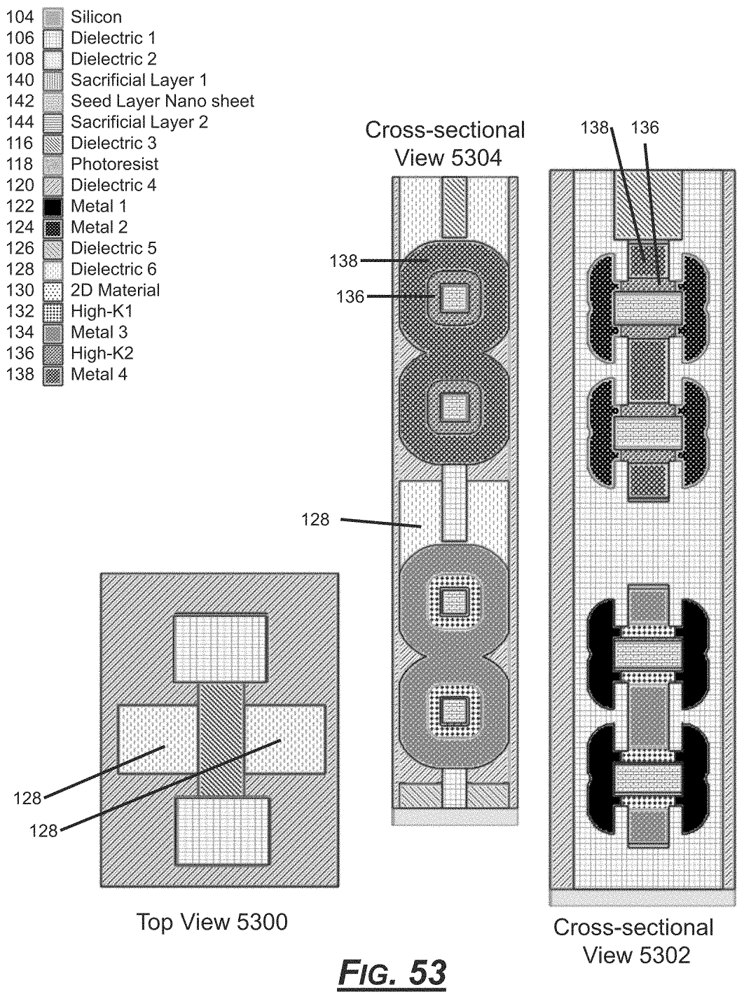

Referring to FIG. 53, illustrated is a top view 5300 and cross-sectional views 5302 and 5304 of the next stage in the process flow. At this stage in the process flow, process steps similar to those described in FIGS. 50-52 can be performed to form the transistor structures in the upper half of the stack of layers. First, the seventh dielectric material 128 can be deposited to fill the remaining gaps in the top of the gate openings, using any suitable material deposition technique. A CMP process may then be performed. Then, the seventh dielectric material 128 can be directionally etched to about halfway through the device, exposing the materials in the stack of layers at the top half of the device in the gate openings. Then, process steps similar to those described in connection with FIGS. 50-52, and others described herein, can be performed to form the 2D material 130, enlarge the source/drain contacts by depositing additional metal material 124, selectively forming the high-k dielectric material 136, and forming the gate metal 138 on the high-k dielectric material 136. In some implementations, a second 2D material, which may have a different polarity than the 2D material 130, can be selectively deposited or selectively formed on the upper layers of the seed material 142. The seventh dielectric material 128 can then be deposited to fill the remaining gaps in the gate openings at the top of the device, and a CMP process may be performed.

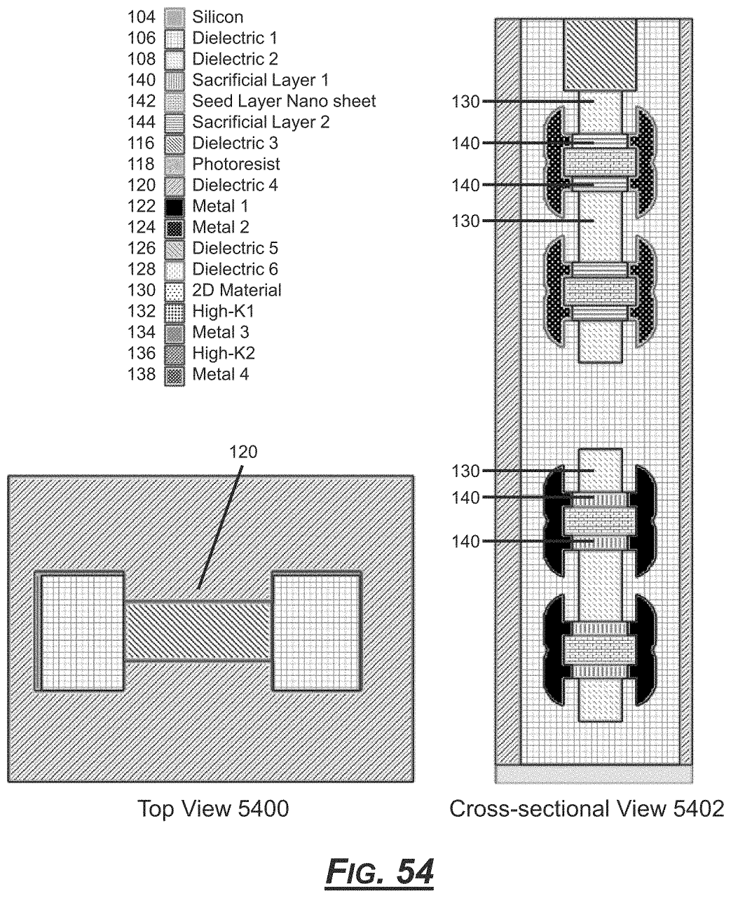

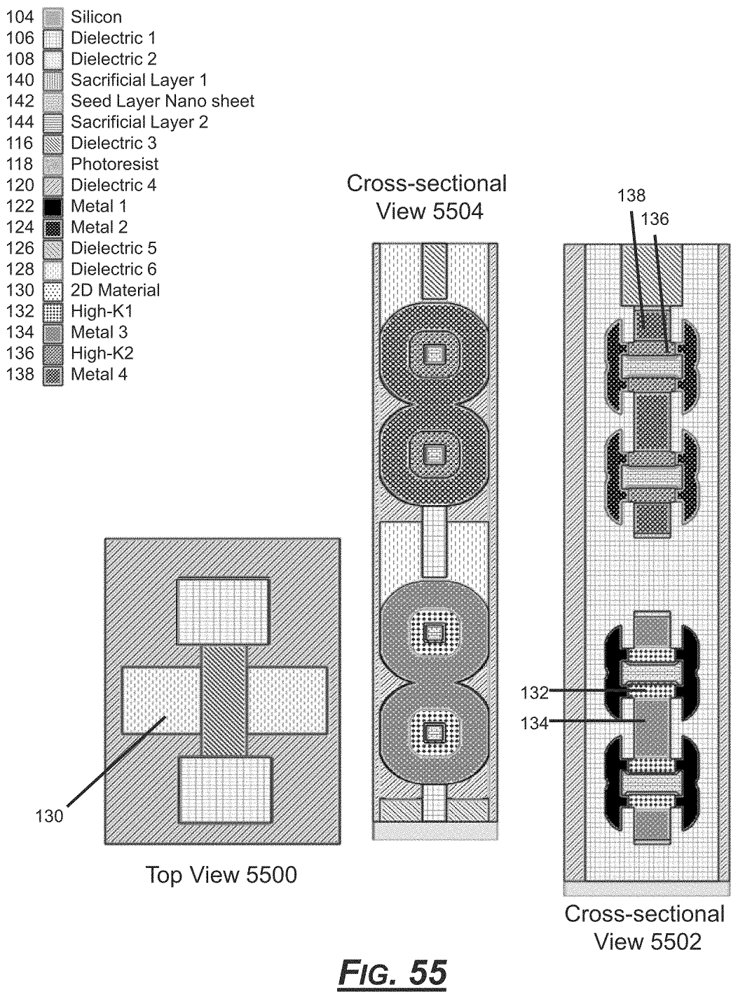

FIGS. 54 and 55 show a process flow similar to that described in connection with FIGS. 47-53. Referring to FIG. 54, illustrated is a top view 5400 and a cross sectional view 5402 of the alternative process flow. At this stage in the process flow, process steps similar to those described in connection with FIGS. 47 and 48 can be performed. However, both the sacrificial material 144 and the second sacrificial material 140 are recessed prior to selectively depositing the metal material 124 and the second metal material 122. The recessing process can be similar to the process described in connection with FIG. 41. Recessing the sacrificial material 144 and the second sacrificial material 140 allows the metal material 124 and the second metal material 122 to have greater contact surface area with the 2D material 130, which is formed in later process steps.

Referring to FIG. 55, illustrated is a top view 5500 and a cross sectional view 5502 of the alternative process flow. At this stage in the process flow, process steps similar to those described in connection with FIGS. 49-53 can be performed to form the transistor structures, as shown. However, prior to selectively forming the 2D material 130 on the seed material 142, the seed material 142 can be partially recessed via the gate openings as described in connection with FIG. 44. To recess the layers of the seed material 142, a selective etching or material removal process may be performed. Any suitable etching or material removal technique can be used to recess the layers of the seed material 142, including but not limited to dry etching, wet etching, or plasma etching techniques, among others. Then, the remainder of the process steps described in connection with FIGS. 51-53 can be performed, to form the 2D material 130, the second high-k dielectric material 132, and the second gate metal 134 in the bottom half of the stack of layers, and to form the 2D material 130, the high-k dielectric material 136, and the second gate metal 138 in the top half of the stack of layers. In some implementations, a second 2D material can be formed in the top or bottom half of the stack of layers, rather than the 2D material 130. The second 2D material may have a polarity (e.g., N-type, P-type, etc.) that is opposite that of the 2D material 130.

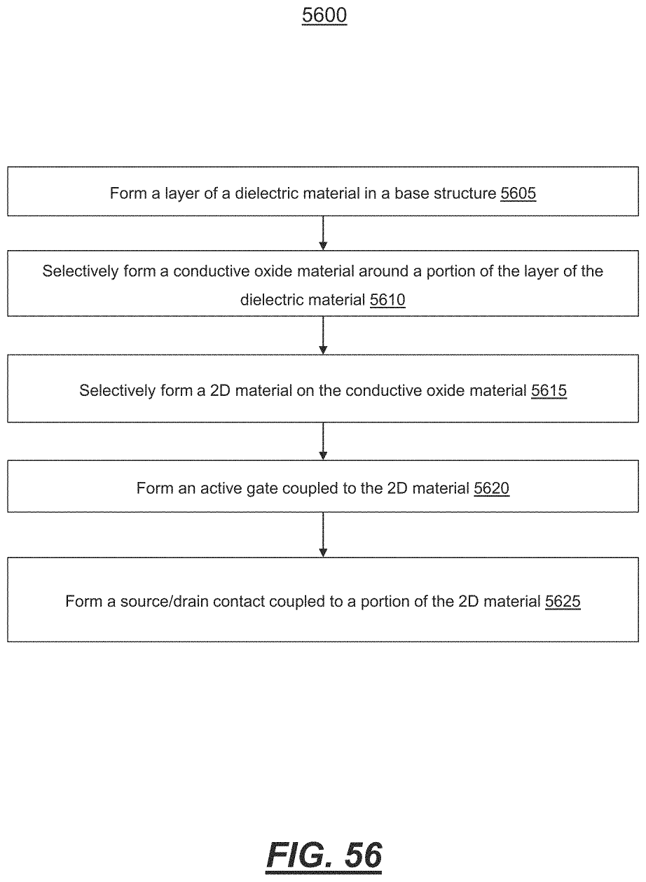

Referring to FIG. 56, illustrated is a flow diagram of a method 5600 for fabricating semiconductor devices. The method 5600 may include steps 5605-5625. However, other embodiments may include additional or alternative steps, or may omit one or more steps altogether.

Referring to step S605, the method includes forming a layer of a dielectric material on a base structure. The base structure can be, for example, a stack of layers, such as the stack of layers described in connection with FIG. 1, or another stack of layers described herein. To form the base structure, process steps similar to those described in connection with FIG. 1, 16, 19, 27, 35, or 47 can be performed. The stack of layers may include a dielectric material (e.g., the third dielectric material 112) and may include one or more layers of a semiconductive-behaving material (e.g., the semiconductive-behaving material 114 or the second semiconductive-behaving material 110).

At step S610, the method 5600 includes selectively forming a conductive oxide material (e.g., the semiconductive-behaving material 114 or the second semiconductive-behaving material 110) surrounding a portion of the layer of the dielectric material. Selectively forming the conductive oxide material may include removing and reforming the conductive oxide material around the layer of the dielectric material. To form the conductive-oxide material, process steps described in connection with FIGS. 2-12 can be performed. The conductive-oxide material may be formed using any suitable material formation technique described herein.

At step S615, the method 5600 includes selectively forming a 2D material (e.g., the 2D material 130) on the conductive oxide material. To do so, process steps similar to those described in connection with FIG. 13, and others described herein, can be performed. In some implementations, the 2D material may be selected based on the type or polarity of the conductive oxide material.

At step S620, the method 5600 includes forming an active gate (e.g., gate materials such as the high-k dielectric material 136 and the gate metal 138, or the second high-k dielectric material 132 and the second gate metal 134) in contact with the 2D material. The active gate can include a layer of a high-k dielectric material (e.g., the high-k dielectric material 136 or the second high-k dielectric material 132) and a layer of a gate metal (e.g. the gate metal 138 or the second gate metal 134). To form the high-k dielectric material on the 2D material, process steps similar to those described in connection with FIG. 14, and others, can be performed. To form the gate metal on the high-k dielectric material, process steps similar to those described in connection with FIG. 15, and others, may be performed.

At step S625, the method 5600 includes a source/drain contact (e.g., the metal material 124 or the second metal material 122) in contact with a portion of the 2D material. To form the metal material, process steps similar to those described in connection with FIGS. 5-8 can be performed. In some implementations, the source/drain contacts can be formed prior to forming the 2D material and the active gate. In some implementations, the source/drain contacts can be formed prior to forming the conductive oxide material, which may be formed as part of the base structure.

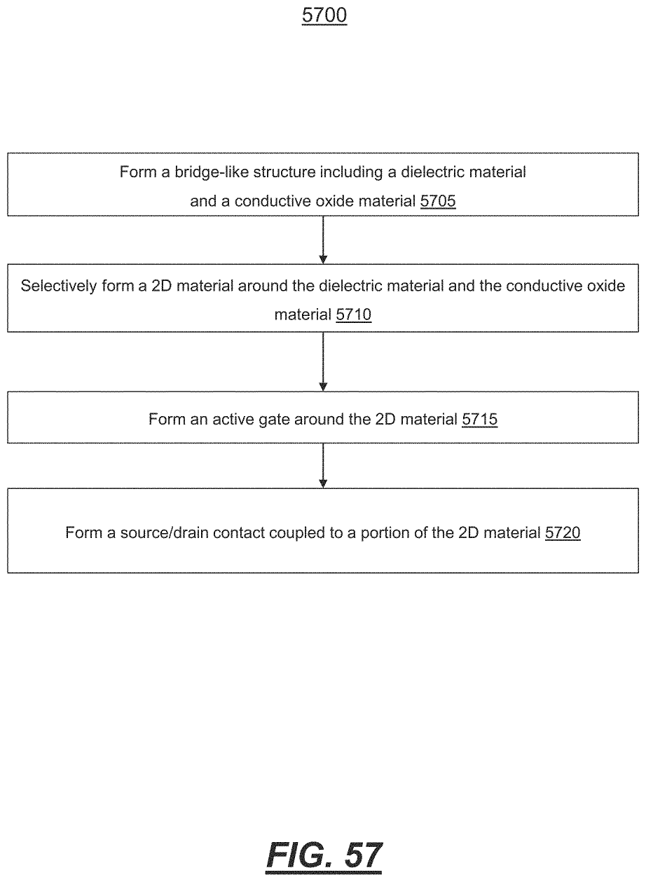

Referring to FIG. 57, illustrated is a flow diagram of a method 5700 for fabricating semiconductor devices. The method 5700 may include steps 5705-5720. However, other embodiments may include additional or alternative steps, or may omit one or more steps altogether.

Referring to step S705, the method includes forming a bridge-like structure including a dielectric material and a conductive oxide material. The bridge-like structure may be formed, for example, in a base structure. The base structure can be, for example, a stack of layers, such as the stack of layers described in connection with FIG. 24, or another stack of layers described herein. To form the base structure, process steps similar to those described in connection with FIG. 24 or 27 can be performed. The stack of layers may include a dielectric material (e.g., the third dielectric material 112) and may include one or more layers of a semiconductive-behaving material (e.g., the semiconductive-behaving material 114 or the second semiconductive-behaving material 110). The bridge-like structure may extend from a first dielectric material to a second dielectric material, and a device having the bridge-like structure may extend from a first source/drain contact to a second source/drain contact.

At step S710, the method 5700 includes selectively forming a 2D material (e.g., the 2D material 130) around the dielectric material and the conductive oxide material. To do so, process steps similar to those described in connection with FIGS. 25 and 26 or FIG. 28, and others described herein, can be performed. In some implementations, the 2D material may be selected based on the type or polarity of the conductive oxide material.

At step S715, the method 5700 includes forming an active gate (e.g., gate materials such as the high-k dielectric material 136 and the gate metal 138, or the second high-k dielectric material 132 and the second gate metal 134) in contact with the 2D material. The active gate can include a layer of a high-k dielectric material (e.g., the high-k dielectric material 136 or the second high-k dielectric material 132) and a layer of a gate metal (e.g. the gate metal 138 or the second gate metal 134). To form the active gate on the 2D material, process steps similar to those described in connection with FIG. 26 or FIG. 28, and others, can be performed.

At step S720, the method 5700 includes a source/drain contact (e.g., the metal material 124 or the second metal material 122) in contact with a portion of the 2D material. To form the metal material, process steps similar to those described in connection with FIG. 25 or 28 can be performed. In some implementations, the source/drain contacts can be formed prior to forming the 2D material and the active gate. In some implementations, the source/drain contacts can be formed prior to forming the conductive oxide material, which may be formed as part of the base structure.

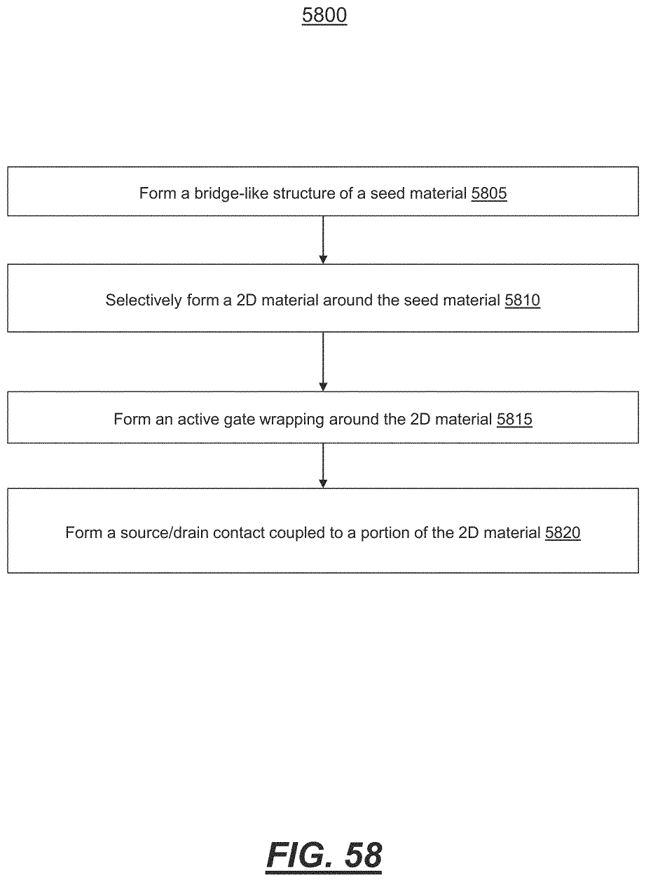

Referring to FIG. 58, illustrated is a flow diagram of a method 5800 for fabricating semiconductor devices. The method 5800 may include steps 5805-5820. However, other embodiments may include additional or alternative steps, or may omit one or more steps altogether.

Referring to step S805, the method includes forming a bridge-like structure including a seed material (e.g., the seed material 142). The bridge-like structure may be formed, for example, in a base structure. The base structure can be, for example, a stack of layers, such as the stack of layers described in connection with FIG. 35 or 47, or another stack of layers described herein. To form the base structure, process steps similar to those described in connection with FIG. 35 or 47 can be performed. The bridge-like structure may extend from a first dielectric material to a second dielectric material, and a device having the bridge-like structure may extend from a first source/drain contact to a second source/drain contact.

At step S810, the method 5800 includes selectively forming a 2D material (e.g., the 2D material 130) around the dielectric material and the seed material. To do so, process steps similar to those described in connection with FIGS. 37, 44 and 45, or 51, and others described herein, can be performed.

At step S815, the method 5800 includes forming an active gate (e.g., gate materials such as the high-k dielectric material 136 and the gate metal 138 or the second high-k dielectric material 132 and the second gate metal 134) in contact with the 2D material. The active gate can include a layer of a high-k dielectric material (e.g., the high-k dielectric material 136 or the second high-k dielectric material 132) and a layer of a gate metal (e.g. the gate metal 138 or the second gate metal 134). To form the active gate on the 2D material, process steps similar to those described in connection with FIG. 40, 46, or 52-53, and others, can be performed.

At step S820, the method 5800 includes a source/drain contact (e.g., the metal material 124 or the second metal material 122) in contact with a portion of the 2D material. To form the metal material, process steps similar to those described in connection with FIG. 36, 42, or 48 can be performed. In some implementations, the source/drain contacts can be formed prior to forming the 2D material and the active gate.

Having now described some illustrative implementations and implementations, it is apparent that the foregoing is illustrative and not limiting, having been presented by way of example. In particular, although many of the examples presented herein involve specific combinations of method acts or system elements, those acts and those elements may be combined in other ways to accomplish the same objectives. Acts, elements and features discussed only in connection with one implementation are not intended to be excluded from a similar role in other implementations or implementations.

The phraseology and terminology used herein is for the purpose of description and should not be regarded as limiting. The use of “including” “comprising” “having” “containing” “involving” “characterized by” “characterized in that” and variations thereof herein, is meant to encompass the items listed thereafter, equivalents thereof, and additional items, as well as alternate implementations consisting of the items listed thereafter exclusively. In one implementation, the systems and methods described herein consist of one, each combination of more than one, or all of the described elements, acts, or components.

“Substrate” or “target substrate” as used herein generically refers to an object being processed in accordance with the invention. The substrate may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

Any references to implementations or elements or acts of the systems and methods herein referred to in the singular may also embrace implementations including a plurality of these elements, and any references in plural to any implementation or element or act herein may also embrace implementations including only a single element. References in the singular or plural form are not intended to limit the presently disclosed systems or methods, their components, acts, or elements to single or plural configurations. References to any act or element being based on any information, act or element may include implementations where the act or element is based at least in part on any information, act, or element.

Any implementation disclosed herein may be combined with any other implementation, and references to “an implementation,” “some implementations,” “an alternate implementation,” “various implementation,” “one implementation” or the like are not necessarily mutually exclusive and are intended to indicate that a particular feature, structure, or characteristic described in connection with the implementation may be included in at least one implementation. Such terms as used herein are not necessarily all referring to the same implementation. Any implementation may be combined with any other implementation, inclusively or exclusively, in any manner consistent with the aspects and implementations disclosed herein.

References to “or” may be construed as inclusive so that any terms described using “or” may indicate any of a single, more than one, and all of the described terms.

Where technical features in the drawings, detailed description or any claim are followed by reference signs, the reference signs have been included for the sole purpose of increasing the intelligibility of the drawings, detailed description, and claims. Accordingly, neither the reference signs nor their absence have any limiting effect on the scope of any claim elements.

The preceding description of the disclosed embodiments is provided to enable any person skilled in the art to make or use the embodiments described herein and variations thereof. Various modifications to these embodiments will be readily apparent to those skilled in the art, and the principles defined herein may be applied to other embodiments without departing from the spirit or scope of the subject matter disclosed herein. Thus, the present disclosure is not intended to be limited to the embodiments shown herein but is to be accorded the widest scope consistent with the following claims and the principles and novel features disclosed herein.

While various aspects and embodiments have been disclosed, other aspects and embodiments are contemplated. The various aspects and embodiments disclosed are for purposes of illustration and are not intended to be limiting, with the true scope and spirit being indicated by the following claims.

What is claimed is:

1. A method, comprising:
forming a dielectric layer;
forming a conductive oxide layer on the dielectric layer;
selectively forming a two-dimensional (2D) material around the conductive oxide layer;
forming an active gate around the 2D material; and
forming a first metal structure and a second metal structure,
wherein the dielectric layer and conductive oxide layer extend between the first metal structure and the second metal structure.

2. The method of claim 1, wherein the conductive oxide layer, first metal structure, and second metal structure are formed on a dielectric.

3. The method of claim 2, wherein forming the conductive oxide layer of the structure comprises:
removing the conductive oxide layer via gate openings; and
forming the conductive oxide layer on the dielectric layer via the gate openings.

4. The method of claim 3, wherein selectively forming the 2D material comprises depositing the 2D material on the conductive oxide layer via the gate openings.

5. The method of claim 1, wherein forming the active gate comprises:
forming a high-k dielectric material on the 2D material; and
forming a gate metal on the high-k dielectric material.

6. The method of claim 1, further comprising forming the first metal structure and the second metal structure in contact with the dielectric layer, the conductive oxide layer, and the 2D material.

7. The method of claim 1, further comprising forming a dielectric material that isolates the first metal structure and the second metal structure from the active gate.

8. The method of claim 1, further comprising:
forming a second dielectric layer;
forming a second conductive oxide layer on the second dielectric layer;
selectively forming a second 2D material around the second conductive oxide layer;
forming a second active gate around the second 2D material; and
forming a third metal structure and a third metal structure,
wherein the second dielectric layer and second conductive oxide layer extend between the third metal structure and the fourth metal structure.

9. The method of claim 1, wherein the first metal structure and the second metal structure are selectively deposited in contact with the conductive oxide layer.

10. A device, comprising:
a dielectric extending from a first source/drain contact to a second source drain contact;
a conductive oxide material on a portion of the dielectric;
a 2D material around the dielectric and extending from the first source/drain contact to the second source drain contact; and
an active gate around the 2D material.

11. The device of claim 10, wherein the active gate is isolated from the first source/drain contact by a dielectric material.

12. The device of claim 10, wherein the active gate comprises:
a high-k dielectric material around a portion of the 2D material; and
a gate metal around a portion of the high-k dielectric material.

13. The device of claim 10, wherein the conductive oxide material is formed around the dielectric.

14. The device of claim 10, wherein the 2D material is an N-type material or a P-type material.

15. The device of claim 10, further comprising:
a second dielectric extending from a third source/drain contact to a fourth source drain contact;
a second conductive oxide material on a portion of the second dielectric;
a second 2D material around the second dielectric and extending from the third source/drain contact to the fourth source drain contact; and
a second active gate around the second 2D material.

16. The device of claim 15, wherein:
the dielectric, conductive oxide material, 2D material, active gate, first source/drain contact, and second source drain contact form a first transistor structure,
the second dielectric, second conductive oxide material, second 2D material, second active gate, third source/drain contact, and fourth source drain contact form a second transistor structure, and
the second transistor structure is disposed above the first transistor structure and separated by a third dielectric.

17. The device of claim 15, wherein the 2D material is an N-type material, and the second 2D material is a P-type material.

18. A transistor structure, comprising:
a source metal;
a drain metal;
a two-dimensional (2D) channel material around a portion of a seed layer nanosheet that extends between the source metal and the drain metal;
a high-k dielectric around a portion of the 2D channel material; and
a gate metal around a portion of the high k-dielectric and isolated from the source metal and the drain metal by a dielectric material.

19. The transistor structure of claim 18, wherein the source metal and the drain metal are in contact with a portion of the high-k dielectric.

20. The transistor structure of claim 18, wherein the source metal and the drain metal are ink contact with the 2D channel material.
